(19) United States
(12) Patent Application Publication
(10) Pub. No.: US 2026/0089856 A1
(43) Pub. Date: Mar. 26, 2026

(54) SEALABLE COVERS FOR ELECTRICAL DEVICES

(71) Applicant: Hubbell Incorporated, Shelton, CT (US)

(72) Inventors: Roy Joseph Itzler, Orange, CT (US); Samuel Thomas Suica, Las Vegas, NV (US)

(21) Appl. No.: 19/317,989

(22) Filed: Sep. 3, 2025

Related U.S. Application Data
(60) Provisional application No. 63/785,090, filed on Apr. 8, 2025.
(60) Provisional application No. 63/697,797, filed on Sep. 23, 2024.

(51) Int. Cl. H05K 5/02; H05K 5/03

(52) U.S. Cl. CPC H05K 5/0221; H05K 5/03; H05K 5/0226

(57) ABSTRACT

A cover assembly for an electrical device having a housing, a lid, a hinge assembly that pivotably couples the lid to the housing, and a cover seal assembly. The cover seal assembly includes a first sealing tab that extends from the lid and a second sealing tab that extends from the housing. The first and second sealing tabs define apertures that align when the lid is in a closed position and are configured to interact with the cover seal assembly such that the lid is sealed in the closed position.

### CROSS-REFERENCE TO RELATED APPLICATIONS

The present application is based on and claims benefit from co-pending U.S. Provisional Patent Application No. 63/697,797 filed September 23, 2024 entitled “Sealable Covers for Electrical Devices” and from co-pending U.S. Provisional Application No. 63/785,090 filed April 8, 2025 entitled “Sealable Covers for Electrical Devices” the contents of each are incorporated herein in their entirety by reference.

### FIELD

The present disclosure relates generally to cover assemblies for electrical devices, and more particularly, to cover assemblies for panel mount receptacles and other electrical wiring devices.

### DESCRIPTION OF THE RELATED ART

In many industrial and commercial indoor and outdoor environments single pole panel mount receptacles are used with cabling to provide electrical power for numerous applications, such as to supply power to machinery, generators, to lighting systems and sound stages, to amusement park rides, and to sporting stadiums. Such single pole panel mount receptacles may be male or female receptacles and include a receptacle housing and a male or female electrical contact within the housing. Some single pole panel mount receptacles are mounted to an interior of a housing, electrical box or other enclosure, such that a portion, e.g., the receptacle housing and electrical contact, of the single pole panel mount receptacle may be exposed to environmental conditions necessitating the covering of a portion of the single pole panel mount receptacle exposed to environmental conditions. Some covers are weather protective covers, e.g., weather protective lift covers, that include a gasket on an interior of the lid of the cover to seal an opening in the cover that provides access to the electrical contact of the single pole panel mount receptacle to which the cover is attached. Further, current covers can be easily opened to gain access to the single pole panel mount receptacle. As a result, users who carelessly use the covers may be able to inadvertently make contact with live electrical contacts.

Thus, there is a need for cover assemblies for electrical devices that include a cover seal assembly that seals the lid to a body to increase the difficulty for users to gain access to electrical devices within the cover assemblies.

### SUMMARY

The present disclosure provides embodiments of cover assemblies for securing electrical devices from unauthorized access. In an exemplary embodiment, a cover assembly includes a housing, a lid, a hinge assembly and a cover seal assembly. The housing includes a mounting flange and a body extending from the mounting flange. The hinge assembly pivotably couples the lid to the housing. The cover seal assembly includes a first tab extending from the body of the housing and a second tab extending from the lid. Each of the first tab and the second tab include apertures that are configured to be aligned when the lid is in a closed position. The cover assembly may include a clasp assembly. The clasp assembly is configured to releasably clasp or secure the lid to the body. The clasp assembly includes a first member and a second member that releasably engages the first member. The first member may be a cantilever arm extending from the lid and the second member may be a shelf extending from the body.

In another exemplary embodiment, the cover assembly includes a housing, a lid and a cover seal assembly. The housing includes a mounting flange, a body extending from the mounting flange and an opening through the mounting flange and the body configured to receive at least a portion of the electrical device. The lid is connected to the body and is movable relative to the body between a closed position blocking the opening and an open position permitting access to the opening. The cover seal assembly includes a first sealing tab, a second sealing tab and a seal member. The first sealing tab extends from the body and includes a first aperture therethrough. The second sealing tab extends from the lid and includes a second aperture therethrough. The first sealing tab may include a hollow projection aligned with the first aperture and extending from the first sealing tab so that the hollow projection can be received within the second aperture. Alternatively, the second sealing tab may include a hollow projection aligned with the second aperture and extending from the second sealing tab so that the hollow projection can be received within the first aperture. When the lid is in the closed position, the first aperture aligns with the second aperture, and at least a portion of the seal member, e.g., a shackle, can be passed through the first and second apertures and at least partially into a locking body of the seal member so that cover seal assembly seals the lid to the body discouraging and possibly preventing unauthorized access to the electrical device covered by the cover assembly. The shackle can be irreversibly locked to the locking body, or the shackle can be removably locked to the locking body. The shackle may be, for example, a flexible cable or a rigid bar. The cover assembly may also include a clasp assembly configured to clasp the lid to the housing. In an exemplary embodiment, the clasp assembly includes a first member extending from the lid configured to engage, e.g., releasably engage, a second member extending from the housing. A non-limiting example of a clasp assembly is a snap-fit connection.

In another exemplary embodiment, the cover assembly includes a housing, a lid and a cover seal assembly. The housing includes a mounting flange, a body extending from the mounting flange and an opening through the mounting flange and the body configured to receive at least a portion of the electrical device. The lid is connected to the body and is movable relative to the body between a closed position blocking the opening and an open position permitting access to the opening. The cover seal assembly includes a first sealing tab, a second sealing tab and a seal member. The first sealing tab extends from the body and includes a first aperture therethrough. The second sealing tab extends from the lid and includes a second aperture therethrough. The first sealing tab may include a hollow projection aligned with the first aperture and extending from the first tab so that the hollow projection can be received within the second aperture. Alternatively, the second sealing tab may include a hollow projection aligned with the second aperture and extending from the second sealing tab so that the hollow projection can be received within the first aperture. When the lid is in the closed position, the first aperture aligns with the second aperture, and a shackle of the seal member can be passed through the first and second apertures and at least partially into a locking body of the seal member to lock the shackle to the locking body and seal the lid to the body to discourage and possibly prevent unauthorized access to the electrical device covered by the cover assembly. The shackle can be irreversibly locked to the locking body, or the shackle can be removably locked to the locking body. The shackle may be, for example, a flexible cable or a rigid bar. The cover assembly may also include a clasp assembly configured to releasably clasp or secure the lid to the housing. In an exemplary embodiment, the clasp assembly includes a first member extending from the lid configured to engage, e.g., releasably engage, a second member extending from the housing. A non-limiting example of a clasp assembly is a snap-fit connection.

In another exemplary embodiment, the cover assembly includes a housing, a lid and a cover seal assembly. The housing includes a mounting flange, a body extending from the mounting flange and an opening through the mounting flange. The opening is configured to receive at least a portion of the electrical device. The lid is connected to the body and is movable relative to the body between a closed position blocking the opening and an open position permitting access to the opening. The cover seal system is operatively coupled to the housing and the lid and is configured to assist in preventing the lid from being moved to the open position limiting access to the at least a portion of the electrical device. In an exemplary embodiment, the cover seal system includes a cover seal assembly and a seal member. The cover seal assembly includes a first sealing tab and a second sealing tab. The first sealing tab extends from the body and includes a first aperture therethrough. The second sealing tab extends from the lid and includes a second aperture therethrough. Preferably, the first aperture is configured to align with the second aperture when the lid is in the closed position. The seal member is configured to at least partially pass through the first aperture and the second aperture, such that when the lid is in the closed position, at least a portion of the seal member can be passed through the first and second apertures. In an exemplary embodiment, the at least a portion of the seal member is a shackle, a flexible cable or a rigid bar, passing through the first aperture and the second aperture. The seal member also includes a locking body, and the shackle is irreversibly or reversibly secured to the locking body.

The present disclosure also provides embodiments of a jacket assembly for sealing a lid of a conventional cover to a body of the conventional cover that houses an electrical device in order to discourage and possibly prevent unauthorized access to the electrical device. In an exemplary embodiment, the jacket assembly includes a first half and a second half that is pivotably coupled to the first half. The first half may include a hinge receiving cavity and a lid restrictor or cap. The hinge receiving cavity extends from the first half and is defined by a top wall, a front wall and two side walls. The top wall, front wall, and side walls are configured such that the cavity is sized and dimensioned to accommodate a hinge mechanism of a conventional cover. The top wall of the hinge receiving cavity may also be configured to engage with at least a portion of the hinge mechanism of the conventional cover to prevent the jacket assembly from being removed or pulled off the conventional cover. The lid restrictor or cap is configured to extend in front of or over the lid to surround the lid of the conventional cover and to block the lid of the conventional cover from being opened.

In another exemplary embodiment, the jacket assembly includes a jacket housing, a jacket locking assembly. The jacket housing defines a jacket opening and is configured to fit onto and at least partially surround a conventional electrical device cover. The housing includes a jacket body and a jacket lid connected to the jacket body so that the jacket lid is movable relative to the jacket body between a closed position blocking the jacket opening and an open position permitting access to the jacket opening. The jacket locking assembly includes a first sealing tab, a second sealing tab and a seal member. The first sealing tab extends from the jacket body and includes a first aperture therethrough. The second sealing tab extends from the jacket lid and includes a second aperture therethrough. When the jacket lid is in the closed position, the first aperture aligns with the second aperture, and at least a portion, e.g., a shackle, of the seal member can be passed through the first aperture, the second aperture and at least partially into a locking body of the seal member so that jacket seal assembly seals the jacket lid to the jacket body discouraging and possibly preventing unauthorized access to the electrical device covered by the conventional cover and the jacket assembly. The shackle may be irreversibly locked to the locking body, or the shackle may be removably locked to the locking body. The shackle may be, for example, a flexible cable or a rigid bar.

The present disclosure also provides embodiments of a cover system for covering a plurality of electrical devices mounted to a structure. The cover system includes a plurality of cover assemblies and an interlocking member. Each of the plurality of cover assemblies includes a housing, a lid and a cover seal system. The housing includes a mounting flange, a body extending from the mounting flange and an opening through the mounting flange. The opening is configured to receive at least a portion of one of the plurality of electrical devices. The lid is connected to the body and movable relative to the body between a closed position blocking the opening and an open position permitting access to the opening. The cover seal system is operatively coupled to the housing and the lid. The cover seal system is configured to assist in preventing the lid from being moved to the open position limiting access to at least a portion of the one of the plurality of electrical devices. In exemplary embodiments, each cover seal system includes a cover seal assembly and a seal member. The cover seal assembly includes a first sealing tab and a second sealing tab. The first sealing tab extends from the body and includes a first aperture therethrough. The second sealing tab extends from the lid and includes a second aperture therethrough. The first aperture is configured to align with the second aperture when the lid is in the closed position, and the interlocking member passes through each first aperture and each second aperture. The seal member is configured to be at least partially coupled to the interlocking member to prevent the interlocking member from being removed from each first aperture and each second aperture. The seal member includes a shackle, a flexible cable or a rigid bar, configured to pass through the interlocking member and locking body. The shackle can be irreversibly or reversibly secured to the locking body. The interlocking member is operatively coupled to each of cover seal system to facilitate the sealing each lid to each housing in the closed position. In exemplary embodiments, the interlocking member may include an elongated shaft having an aperture or eyelet at a distal end. In another embodiment, the interlocking member includes an outer hollow member and an inner rod within the outer hollow member. The inner rod is movable within the outer hollow member between a loaded position and a deployed position. The inner rod has an eyelet at a distal end. When the inner rod is in the loaded position, the eyelet is within the outer hollow member, and when the inner rod is in the deployed position, the eyelet extends from a distal end of the outer hollow member.

In another exemplary embodiment, the cover system includes a plurality of cover assemblies, an interlocking member and a seal member. Each cover assembly includes a housing, a lid and a cover seal assembly. The housing has a mounting flange, a body extending from the mounting flange and an opening through the mounting flange. The opening is configured to receive at least a portion of one of the plurality of electrical devices. The lid is connected to the body and is movable relative to the body between a closed position blocking the opening and an open position permitting access to the opening. The cover seal assembly includes a first sealing tab and a second sealing tab. The first sealing tab extends from the body and includes a first aperture therethrough. The second sealing tab extends from the lid and includes a second aperture therethrough. Preferably, the first aperture is configured to align with the second aperture when the lid is in the closed position. The interlocking member is configured to be passed through each first aperture and each second aperture of each cover seal assembly and to facilitate sealing each lid in the closed position. In some embodiments, the interlocking member includes an elongated shaft having an aperture or eyelet at a distal end. The seal member is configured to be at least partially coupled to the interlocking member to prevent the interlocking member from being removed from each first aperture and each second aperture. The seal member may include a shackle, a flexible cable or a rigid bar, passing through the first aperture and the second aperture, and the seal member includes a locking body. The shackle can be irreversibly or reversibly secured to the locking body.

### BRIEF DESCRIPTION OF THE DRAWINGS

To further clarify the above and other advantages and features of the subject matter of this patent specification, specific examples of embodiments thereof are illustrated in the appended drawings. It should be appreciated that these drawings depict only exemplary embodiments and are therefore not to be considered limiting of the scope of this patent specification or the appended claims. The subject matter hereof will be described and explained with additional specificity and detail through the accompanying drawings in which:

FIG. 1 is an exploded perspective view of an electrical device, a structure, and a cover assembly according to the present disclosure that is attachable to the structure;

FIG. 2 is a front perspective view of an exemplary embodiment of a cover assembly according to the present disclosure, illustrating a cover housing, a lid and an exemplary embodiment of a cover seal system;

FIG. 3 is an enlarged perspective view of a portion of the cover assembly of FIG. 2 taken from detail 3, illustrating sealing tabs on the cover housing and lid forming a portion of the cover seal system;

FIG. 4 is a side perspective view of the cover assembly of FIG. 2 with a seal member of the cover seal system removed and the lid in an open position;

FIG. 5 is a side elevation view of the cover assembly of FIG. 2, with a seal member of the cover seal system removed and the lid of the cover assembly in a closed position, and illustrating a cross-sectional view of the sealing tabs forming a portion of the cover seal system;

FIG. 6 is a front perspective view of another exemplary embodiment of a cover assembly according to the present disclosure, illustrating a cover housing, a lid and another exemplary embodiment of the cover seal system according to the present disclosure;

FIG. 7 is an enlarged perspective view of a portion of the cover assembly of FIG. 6 taken from detail 7, illustrating sealing tabs on the cover housing and lid forming a portion of another exemplary embodiment of the cover seal system according to the present disclosure;

FIG. 8 is a side perspective view of a portion of the cover assembly of FIG. 6 with a seal member of the cover seal system removed and the lid in an open position;

FIG. 9 is a side elevation view of the cover assembly of FIG. 6, with seal member of the cover seal system removed and the lid of the cover assembly in a closed position, and illustrating a cross-sectional view of another exemplary embodiment of the sealing tabs forming a portion of the cover seal system;

FIG. 10 is a front perspective view of another exemplary embodiment of a cover assembly according to the present disclosure, illustrating a cover housing, a lid and another exemplary embodiment of the cover seal system according to the present disclosure;

FIG. 11 is an enlarged perspective view of a portion of the cover assembly of FIG. 10 taken from detail 11, illustrating sealing tabs on the cover housing and lid forming a portion of another exemplary embodiment of the cover seal system according to the present disclosure, and an exemplary embodiment of a portion of a locking assembly according to the present disclosure;

FIG. 12 is a side perspective view of a portion of the cover assembly of FIG. 10 with a seal member of the cover seal system removed, the locking assembly in an unlocked position and the lid in an open position;

FIG. 13 is a side elevation view of the cover assembly of FIG. 10, with the seal member of the cover seal system removed and the lid of the cover assembly in a closed position, and illustrating a cross-sectional view of the sealing tabs on the cover housing and lid forming a portion of another exemplary embodiment of the cover seal system according to the present disclosure and the locking assembly of the cover assembly in a locked position;

FIG. 14 is an enlarged side elevation view of a portion of the cover assembly of FIG. 10 showing an enlarged view of the locking assembly of FIG. 13, and illustrating movement of a latch of the locking assembly to the locked position;

FIG. 15 is a front perspective view of another exemplary embodiment of a cover assembly according to the present disclosure, illustrating a cover housing, a lid and another exemplary embodiment of the cover seal system according to the present disclosure;

FIG. 16 is an enlarged perspective view of a portion of the cover assembly of FIG. 15 taken from detail 16, illustrating sealing tabs on the cover housing and lid forming a portion of another exemplary embodiment of the cover seal system according to the present disclosure;

FIG. 17 is a side perspective view of a portion of the cover assembly of FIG. 15 with the seal member of the cover seal system removed and the lid in an open position;

FIG. 18 is a side elevation view of cover assembly of FIG. 15, with the seal member of the cover seal system removed and the lid of the cover assembly in a closed position, and illustrating a cross-sectional view of sealing tabs of the cover seal system;

FIG. 19 is a front perspective view of another exemplary embodiment of a cover assembly according to the present disclosure, illustrating a cover housing, a lid and another exemplary embodiment of the cover seal system according to the present disclosure;

FIG. 20 is an enlarged perspective view of a portion of the cover assembly of FIG. 19 taken from line 20-20, illustrating a partial cross-section of sealing tabs on the cover housing and lid and a portion of a seal member forming a portion of the cover seal system;

FIG. 21 is a side perspective view of cover assembly of FIG. 19 with the seal member of the cover seal system removed and the lid in an open position;

FIG. 22 is a side elevation view of cover assembly of FIG. 19 with the seal member of the cover seal system removed and the lid of the cover assembly in a closed position, and illustrating a cross-sectional view of the sealing tabs on the cover housing and lid;

FIG. 23 is a front perspective view of an exemplary embodiment of a jacket assembly according to the present disclosure covering a conventional cover assembly, and illustrating a jacket body, a jacket lid and an exemplary embodiment of a jacket seal system according to the present disclosure;

FIG. 24 is an exploded front perspective view of the jacket assembly and conventional cover assembly of FIG. 23, illustrating the jacket assembly staged for mounting onto the conventional cover assembly;

FIG. 25 is a side elevation view of the jacket assembly mounted to the conventional cover assembly of FIG. 23, illustrating the jacket assembly in cross-section revealing the conventional cover assembly within the jacket assembly;

FIG. 26 is an enlarged perspective view of a portion of the jacket assembly and conventional cover assembly of FIG. 23, illustrating the jacket seal system sealing the jacket lid to the jacket body;

FIG. 27 illustrates a front perspective view of another exemplary embodiment of a cover assembly according to the present disclosure, illustrating a cover housing, a lid and another exemplary embodiment of a cover seal system according to the present disclosure;

FIG. 28 is a front perspective view of the cover assembly of FIG. 27, with a seal member of the cover seal system removed and the lid in an open position;

FIG. 29 is an enlarged perspective view of a portion of the cover seal system of the cover assembly of FIG. 27 taken from detail 29, illustrating sealing tabs on the cover housing and lid forming a portion of the cover seal system and a portion of the seal member forming a portion of the cover seal system;

FIG. 30 is a front perspective view showing a plurality of cover assemblies according to another exemplary embodiment of the present disclosure, illustrating each cover assembly having a cover housing and a lid, and illustrating another exemplary embodiment of a cover seal system according to the present disclosure;

FIG. 31 is a front perspective view of the plurality of cover assemblies similar to FIG. 30, illustrating a seal member of the cover seal system removed and the lid of one of the cover assemblies in an open position;

FIG. 32 is a perspective view of an exemplary embodiment of a seal member according to the present disclosure, illustrating a rigid shaft, a handle at first end of the shaft and an opening through the shaft at or near a second end of the shaft;

FIG. 33 is a perspective view of another exemplary embodiment of a seal member according to the present disclosure, illustrating a flexible shaft, a handle at first end of the shaft and an opening through the shaft at or near a second end of the shaft;

FIG. 34 is a perspective view of another exemplary embodiment of a seal member according to the present disclosure, illustrating a flexible cable as the shaft, a handle at first end of the shaft and an opening or loop at or near a second end of the shaft;

FIG. 35 is a perspective view of another exemplary embodiment of a seal member according to the present disclosure, illustrating an outer shaft and an inner shaft telescopically associated with the outer shaft;

FIG. 36 is a partial cross-sectional view of the seal member of FIG. 35, illustrating the inner shaft and a loop at a distal end of the inner shaft within the outer shaft;

FIG. 37 is a partial cross-sectional view of the seal member of FIG. 35, illustrating the inner shaft and a loop at a distal end of the inner shaft extending from a distal end of the outer shaft;

FIG. 38 is a front elevation view showing the plurality of cover assemblies of FIG. 30 with lids sealed using the seal member of FIG. 33;

FIG. 39 is a front elevation view showing the plurality of cover assemblies of FIG. 30 with lids sealed using the seal member of FIG. 34;

FIG. 40 is a front elevation view showing the plurality of cover assemblies of FIG. 30 with lids sealed using the seal member of FIG. 35;

FIG. 41 is a front perspective view showing a plurality of cover assemblies similar to FIG. 30, illustrating one cover assembly offset from the other cover assemblies and the seal member of FIG. 33 flexing so that the seal member of the cover seal system can be coupled to each cover assembly;

FIG. 42 is a front perspective view of another exemplary embodiment of a cover assembly according to the present disclosure, illustrating a portion of the housing body, the lid in a closed position, and a portion of another exemplary embodiment of a cover seal system;

FIG. 43 is a front perspective view of the cover assembly of FIG. 42, illustrating the portion of the housing body, the lid in an open position, and a portion of the cover seal system;

FIG. 44 is a front perspective view of the cover assembly of FIG. 42, illustrating the portion of the housing body, the lid in the closed position, and the cover seal system with a seal member of FIG. 32 or 33;

FIG. 45 is a front perspective view of the cover assembly of FIG. 42, illustrating the portion of the housing body, the lid in the closed position, and the cover seal system with a seal member of FIG. 34;

FIG. 46 is a front perspective view of the cover assembly of FIG. 42, illustrating the portion of the housing body, the lid in the closed position, and the cover seal system with a seal member of FIG. 35;

FIG. 47 is a front perspective view showing a plurality of conventional cover assemblies each having another exemplary embodiment of a jacket assembly according to the present disclosure mounted thereon, illustrating the seal member of FIG. 34 as part of a jacket seal system coupled to each jacket assembly;

FIG. 48 is a front perspective view of a jacket assembly and conventional cover assembly of FIG. 47, illustrating a jacket body, a jacket lid and the jacket seal system with a portion of the seal member of FIG. 34;

FIG. 49 is a partial cross-sectional view of the jacket assembly of FIG. 48 taken from line 49-49 and illustrating a locking mechanism for locking the jacket assembly to the conventional cover assembly;

FIG. 50 is an exploded front perspective view of the jacket assembly of FIG. 48 and conventional cover assembly of FIG. 23, illustrating the jacket assembly staged for insertion onto the conventional cover assembly;

FIG. 51 is a front perspective view of the jacket assembly and conventional cover assembly of FIG. 48, illustrating a jacket body, a jacket lid and the jacket seal system with a portion of the seal member of FIG. 32;

FIG. 52 is a front perspective view of a jacket assembly and conventional cover assembly of FIG. 48, illustrating a jacket body, a jacket lid and the jacket seal system with a portion of the seal member of FIG. 33;

FIG. 53 is a front perspective view of a jacket assembly and conventional cover assembly of FIG. 48, illustrating a jacket body, a jacket lid and the jacket seal system with a portion of the seal member of FIG. 35;

FIG. 54 is an exploded front perspective view of another exemplary embodiment of a jacket assembly according to the present disclosure and conventional cover assembly of FIG. 23, illustrating the jacket assembly staged for insertion onto the conventional cover assembly; and

FIG. 55 is a perspective view of the jacket assembly of FIG. 54 mounted to the conventional cover assembly of FIG. 54, illustrating portions of the optional seal members of FIGS. 32-35 staged for insertion into openings in first and second sealing tabs of the jacket assembly.

### DETAILED DESCRIPTION

A detailed description of examples of preferred embodiments is provided below. While several embodiments are described, the new subject matter described in this patent specification is not limited to any one embodiment or combination of embodiments described herein, but instead encompasses numerous alternatives, modifications, and equivalents. In addition, while numerous specific details are set forth in the following description to provide a thorough understanding, some embodiments can be practiced without some or all such details. Moreover, for the purpose of clarity, certain technical material that is known in the related art has not been described in detail in order to avoid unnecessarily obscuring the new subject matter described herein. It should be clear that individual features of one or several of the specific embodiments described herein can be used in combination with features of other described embodiments or with other features. Further, like reference numbers and designations in the various drawings indicate like elements.

The present disclosure provides exemplary embodiments of cover assemblies for electrical devices that at least partially surround electrical devices, and of jacket assemblies that at least partially surround conventional covers that cover electrical devices. Non-limiting examples of electrical devices contemplated by the present disclosure include single pole panel mount male receptacles, single pole panel mount female receptacles. For ease of description, the electrical devices may also be referred to herein collectively as the “devices” in the plural, and the “device” in the singular. In the exemplary embodiments shown, the novel cover assemblies include a cover housing and at least one lid or cover, e.g., movable lid or cover, that can be sealed in a closed position to discourage and possibly prevent unauthorized access to the electrical device covered by the cover assemblies. For ease of description, the cover assemblies according to the present disclosure may also be referred to herein collectively as the “covers” in the plural, and the “cover” in the singular. The jacket assemblies include a jacket body and a movable jacket lid or cover, e.g., a hinged lid or cover, that can be sealed in a closed position to discourage and possibly prevent unauthorized access to the electrical device covered by conventional covers. The jacket assemblies are configured and dimensioned to fit over conventional covers, such as the HBLNC, Single Pole Weatherproof Lift Covers, manufactured by Hubbell Incorporated, that cover electrical devices. The jacket assemblies according to the present disclosure may also be referred to herein collectively as the “jackets” in the plural, and the “jacket” in the singular.

The cover assemblies described herein may be made of materials that are sufficiently rigid to protect the electrical devices or portions of the electrical devices housed within the cover assemblies from being damaged. Preferably, the cover assemblies described herein are made from materials that further protect the electrical devices or portions of the electrical devices housed within the cover assemblies from environmental conditions, such as snow, rain, cold and heat. Preferably, the cover assemblies according to the present disclosure may be made of plastic materials or other non-conductive materials. Non-limiting examples of such plastic materials include thermoplastic materials or combinations of thermoplastic materials. Non-limiting examples of thermoplastic materials include Polycarbonate, Polybutylene Terephthalate (PBT) and Nylon. However, one skilled in the art would understand and appreciate that cover assemblies described herein can be made in other ways and from alternative materials without deviating from the scope contemplated by the present disclosure.

The jacket assemblies described herein may be made of materials that are sufficiently rigid to cover and protect conventional covers or portions of the conventional covers housed within the jacket assemblies from being damaged. Preferably, the jacket assemblies described herein are made from materials that may further protect the conventional covers or portions of the conventional covers housed within the jacket assemblies from environmental conditions, such as snow, rain, cold and heat. The jacket assemblies according to the present disclosure may be made of plastic materials or other non-conductive materials. Non-limiting examples of such plastic materials include thermoplastic materials or combinations of thermoplastic materials. Non-limiting examples of thermoplastic materials include Polycarbonate, Polybutylene Terephthalate (PBT) and Nylon. However, one skilled in the art would understand and appreciate that cover assemblies described herein can be made in other ways and from alternative materials without deviating from the scope contemplated by the present disclosure.

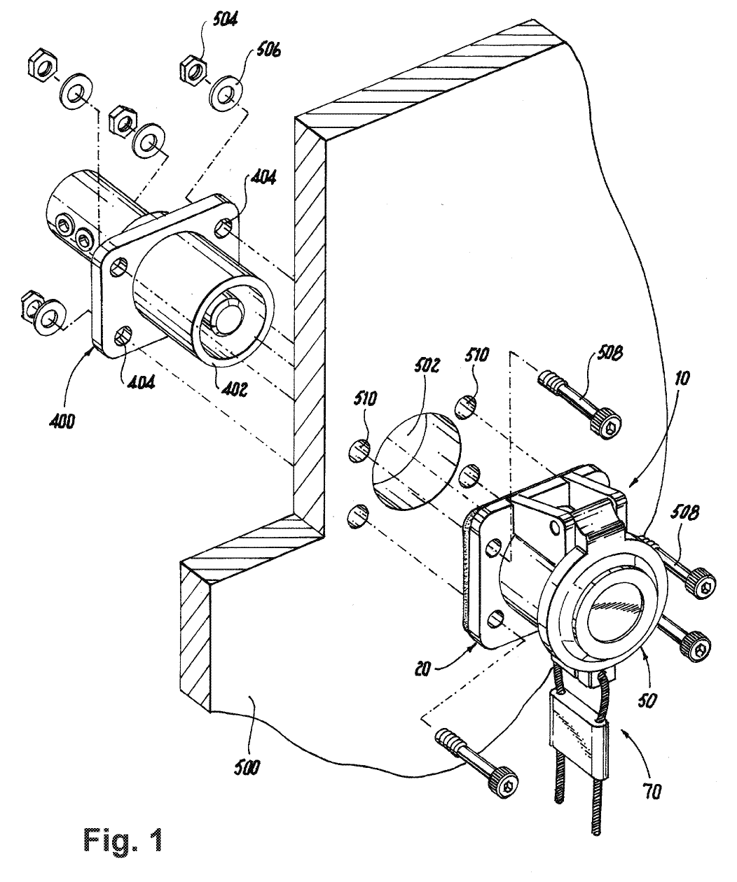

Referring to FIG. 1, the cover assemblies 10 contemplated by the present disclosure are generally provided to cover at least a portion of one or more electrical devices 400 extending from a structure 500, typically outside a structure, as shown in FIG. 1. In some configurations, the electrical device 400 is positioned on one side of the structure 500 with a contact portion 402 of the electrical device 400 passing through an opening 502 in the structure 500, and the cover assembly 10 is positioned on another side of the structure 500. The cover assembly 10 and electrical device 400 are then secured to the structure 500 using fasteners, such as nuts 504, washers 506 and bolts 508, where the bolts 508 pass through mounting holes in the housing of the cover assembly 10, mounting holes 510 in the structure 500 and mounting holes 404 in the electrical device 400. In the exemplary embodiments shown and described herein, the cover assemblies 10 are described as covering at least a contact portion 402 of single pole electrical devices 400 extending outside the structure 500 and exposed to environmental conditions. Nonlimiting examples of structures 500 the electrical devices and cover assemblies 10 can be secured to include sheds, housings, electrical boxes or other enclosures. However, the present disclosure contemplates embodiments where a cover assembly 10 can be configured to cover more than one electrical device 400 in a multi-gang like configuration, such as a double or triple gang configuration. In such embodiments, the cover assembly 10 may have one or more lids.

Referring to FIGS. 1-5, an exemplary embodiment of a cover assembly according to the present disclosure is shown. The cover assembly 10 includes a housing 20, a lid 50, and a cover seal system 70. The housing 20 includes a body 22 and a mounting flange 24. The mounting flange 24 includes an opening that receives the body 22 so that the body 22 extends from the mounting flange 24. The body 22 may be integrally or monolithically formed into the flange 24, or the body 22 may be secured to the flange 24 by, for example, welded joints, adhesives or fasteners. In the embodiment shown, the housing body 22 is a substantially cylindrical body having a circular opening 26 that is in communication with the flange opening and is configured to receive at least a portion of the electrical device 400. However, it is contemplated the shape of the body 22 and opening 26 may be any shape sufficient to receive at least a portion of the electrical device. For example, the shape of the body 22 and opening 26 may be any number of polygonal and nonpolygonal shapes, such as, for example, triangular, rectangular, oval or square. In the embodiment shown, the flange 24 is substantially planar and configured to be attached to a structure 500. For example, the flange 24 may be secured to the structure 500 utilizing one or more fasteners 28. The fasteners 28 may be mechanical fasteners, such as nuts and bolts, screws, nails or other mechanical fasteners, that pass through one or more corresponding mounting holes in the flange 24 and into the structure 500 such that the cover assembly 10 is secured to the structure 500. In alternative embodiments, the fasteners 28 can be passed through one or more corresponding mounting holes in the flange 24, through into mounting holes 510 in the structure 500, and through mounting holes on the electrical device 400, seen in FIG. 1, such that the cover assembly 10 is secured to the structure 500 and to the electrical device 400. A seal member 25, e.g., a gasket, may be positioned between the flange 24 and the structure 500 to seal the opening 502 in the structure 500, seen in FIG. 1, through which at least the contact portion 402 of the electrical device 400 passes through the structure 500.

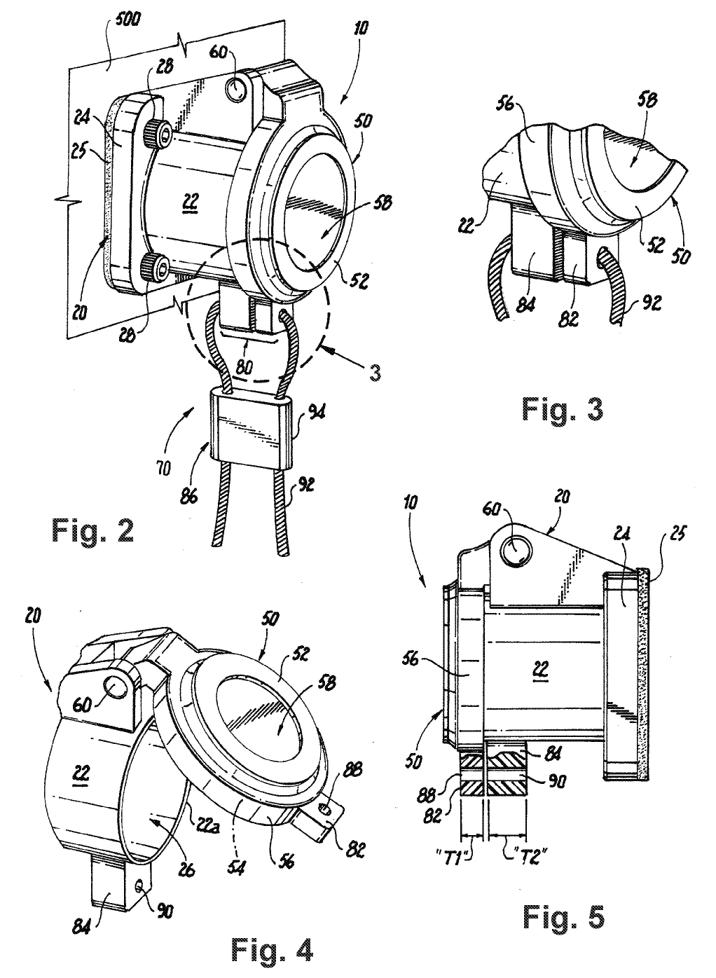

Continuing to refer to FIGS. 2-5, in the exemplary embodiment shown, the lid 50 is coupled to the housing 20 and is preferably movable between an open position, seen in FIG. 4, and a closed position, seen in FIG. 2. When the lid 50 is in the open position, a user has access to the opening 26 and thus to the portion of the electrical device 400 within the opening 26. For example, if the electrical device 400 within the opening 26 is a single pole female receptacle, the user would have access to the female contact within the opening 26. When the lid 50 is in the closed position, access to the opening 26 in the housing body 22 is blocked. The lid 50 is configured and dimensioned to cover and enclose the opening 26 in the body 22. In the embodiment shown, the lid 50 is a circular member having an exterior surface 52, an interior surface 54 and a wall 56 around a perimeter of the lid 50 as shown in FIG. 4. The interior surface 54 of the lid 50 contacts the distal edge 22a of the housing body 22 and the wall 56 encloses distal edge 22a when the lid 50 is in the closed position. A perimeter of the interior surface 54 of the lid 50 may include a seal member (not shown) that seals the opening 26 of the body 22 from environmental conditions when the lid 50 is in the closed position. Sealing the opening 26 of the body 22 with the lid 50 provides a weatherproof cover for the electrical device 400. In some embodiments, at least a portion of the lid 50 may provide a transparent window 58 for inspecting the electrical device 400 or the portion 402 of the electrical device 400 within the cover assembly 10. In an exemplary embodiment, the window 58 may be made of a transparent material, such as a transparent plastic material.

As noted above, the lid 50 is preferably coupled to the housing 20 so that the lid 50 is movable between open position and closed positions. In the embodiment shown, the lid 50 is hinged to the body 22 and pivots about an axis using one or more pivot pins 60 so that the lid 50 pivots upward to the open position and pivots downward to the closed position. In this exemplary embodiment, the lid 50 may also be known as a lift lid. However, the present disclosure contemplates that lid 50 may be configured to pivot in any number of directions to the open position. Likewise, the lid 50 may be configured to pivot in any number of directions to the closed position. Preferably, the hinge coupling the lid 50 to the body 22 includes a biasing member (not shown), e.g., a spring, so that the lid 50 is automatically biased to the closed position. A non-limiting example of a spring includes a torsion spring that automatically biases and pivots the lid 50 to the closed position.

Continuing to refer to FIGS. 2-5, the cover seal system 70 of the cover assembly 10 is configured to discourage and possibly prevent the lid 50 from being moved to the open position and thus discourage and possibly prevent unauthorized access to the electrical device 400 or the portion of the electrical device 400 within the cover assembly 10. Further, the cover seal system 70 may also provide evidence of tampering. In the embodiment shown in FIGS. 2-5, the cover seal system 70 includes a cover seal assembly 80 and seal member or assembly 86. For ease of description, the seal member or assembly may also be referred to herein as the seal member 86 so that the present disclosure contemplates that the seal member 86 may be a member or an assembly.

In the exemplary embodiment of FIGS. 2-5, the cover seal assembly 80 includes a first sealing tab 82 and a second sealing tab 84. The first sealing tab 82 is a solid member with a rectangular or square shaped cross-section that extends from the lid 50 and includes an aperture 88 therethrough. The first sealing tab 82 may be integral with or monolithically formed into the wall 56 around a perimeter of the lid 50, or the first sealing tab 82 may be secured to the wall 56 with for example welded joints or adhesives. The first sealing tab 82 has a predefined thickness “T1” that is sufficient to withstand accidental contact without breaking. In the embodiment shown, the predefined thickness “T1” of the first sealing tab 82 is the same size as the wall 56 around a perimeter of the lid 50. The second sealing tab 84 is a solid member with a rectangular or square shaped cross-section that extends from the body 22 and includes an aperture 90 therethrough. The second sealing tab 84 may be integral with or monolithically formed into the body 22, or the second sealing tab 84 may be secured to the body 22 with for example welded joints or adhesives. The second sealing tab 84 has a predefined thickness “T2” that is sufficient to withstand accidental contact without breaking. In the embodiment shown, the predefined thickness “T2” of the second sealing tab 84 is larger than the thickness “T1” of the first sealing tab 82.

The first and second sealing tabs 82 and 84 are positioned on the lid 50 and body 22, respectively, so that when the lid 50 is in the closed position, the apertures 88 and 90 are in alignment with each other such that at least a portion of the seal member 86 can pass through the apertures 88 and 90 when sealing the lid 50 to the body 22. The seal member 86 is provided to seal the lid 50 to the body 22 to discourage and possibly prevent unauthorized access to the electrical device 400 covered by the cover assembly 10. In this exemplary embodiment, the seal member 86 is an irreversible seal member where once sealed the seal member cannot be unsealed without cutting or otherwise breaking the seal member 86. Non-limiting examples of irreversible seal members 86 include meter-like tags, security seals, zip-ties and tie-wraps. An example of a security seal is the Cablelock 1.5 aluminum bodied cable seal, sold by American Casting and Manufacturing (https://seals.com/1-5-mm-barcoded-cable-seal-cablelock-1-5/). In the embodiment shown, the seal member 86 includes a shackle 92, e.g., a flexible cable or rigid bar, and an irreversible locking body 94. To seal the seal member 86 to the cover assembly 10, one end of the shackle 92 is passed through the aperture 88 in the first sealing tab 82, through the aperture 90 in the second sealing tab 84 and through or at least partially into the locking body 94 so that the end of the shackle 92 can be locked in the locking body 94. When the shackle 92 is locked to the locking body 94, the lid 50 is sealed to the body 22 to discourage and possibly prevent unauthorized access to the electrical device 400 covered by the cover assembly 10. To break the seal, the shackle 92 would have to be cut. However, in some embodiments, the locking body 94 of the seal member 86 may have locking mechanism with a key or combination that can be used to unlock the locking mechanism so the shackle 92 can be removed from the locking body 94 to break the seal. A non-limiting example of a seal member with a locking mechanism includes cable luggage locks. An example of a cable luggage lock is the Pack All, 3 Digit Combination TSA Padlock (https://www.packall.cc/products/packall-tsa-approved-cable-luggage-locks).

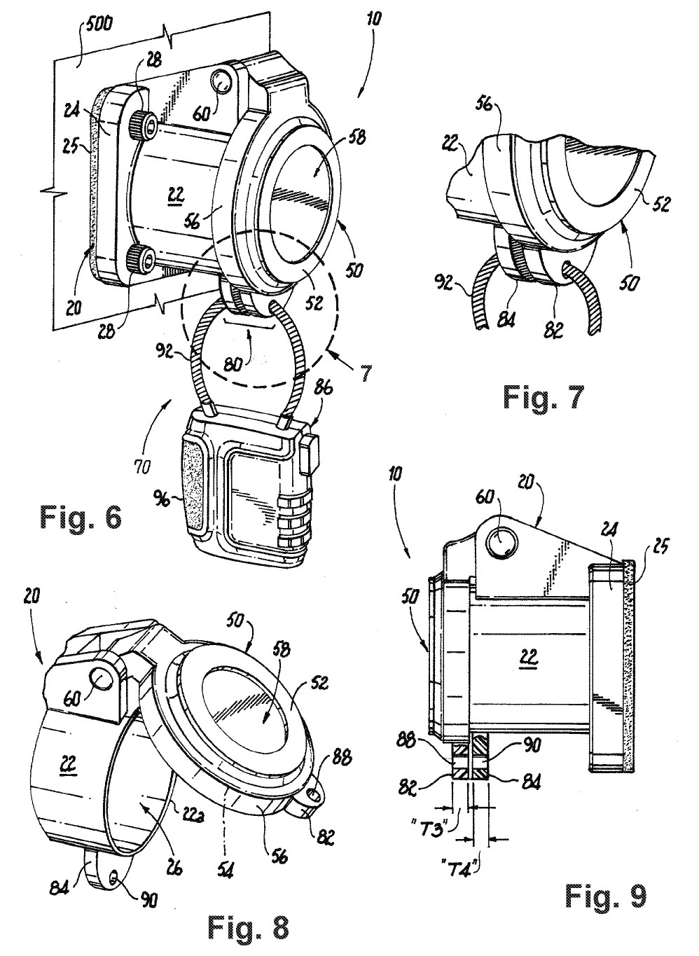

Turning now to FIGS. 6-9, another exemplary embodiment of a cover assembly 10 according to the present disclosure is shown. In this embodiment, the cover assembly 10 includes a housing 20, a lid 50, and a cover seal system 70. The housing 20 and lid 50 are substantially the same as the housing and lid described in relation to FIGS. 2-5 and are not repeated. In this exemplary embodiment, the cover seal system 70 differs from the embodiment described above. More specifically, the shape and dimensions of the sealing tabs 82 and 84 of the cover seal assembly 80 differ, and the seal member 86 includes a locking body 96 having a locking mechanism. In the embodiment shown, the first sealing tab 82 is a solid member with an arcuate shaped cross-section, e.g., a quarter moon shape, that extends from the lid 50 and includes an aperture 88 therethrough. The first sealing tab 82 may be integral with or monolithically formed into the wall 56 around a perimeter of the lid 50, or the first sealing tab 82 may be secured to the wall 56 with for example welded joints or adhesives. The first sealing tab 82 has a predefined thickness “T3” that is sufficient to withstand accidental contact without breaking. In the embodiment shown, the predefined thickness “T3” of the first sealing tab 82 is the smaller than the size of the wall 56 around a perimeter of the lid 50. The second sealing tab 84 is a solid member with an arcuate shaped cross-section, e.g., a quarter moon shape, that extends from the body 22 and includes an aperture 90 therethrough. The second sealing tab 84 may be integral with or monolithically formed into the body 22, or the second sealing tab 84 may be secured to the body 22 with for example welded joints or adhesives. The second sealing tab 84 has a predefined thickness “T4” that is sufficient to withstand accidental contact without breaking. In the embodiment shown, the predefined thickness “T4” of the second sealing tab 84 is substantially the same as the thickness “T3” of the first sealing tab 82.

Continuing to refer to FIGS. 6-9, in this exemplary embodiment, the seal member 86 is a reversable seal member that includes a locking body having a locking mechanism with a key or combination that can be used to unlock the locking mechanism to break the seal. A non-limiting example of a seal member 86 with a locking mechanism includes cable luggage locks. An example of a cable luggage lock is the Pack All, 3 Digit Combination TSA Padlock (https://www.packall.cc/products/packall-tsa-approved-cable-luggage-locks). An example of a security seal is the Cablelock 1.5 aluminum bodied cable seal, sold by American Casting and Manufacturing (https://seals.com/1-5-mm-barcoded-cable-seal-cablelock-1-5/). /). In the embodiment shown, the seal member 86 includes a shackle 92 and an unlockable locking body 96. To seal the seal member 86 to the cover assembly 10, one end of the shackle 92 is passed through the aperture 88 in the first sealing tab 82, through the aperture 90 in the second sealing tab 84 and at least partially into the locking body 96 and locked. When the shackle 92 is locked to the locking body 94, the lid 50 is sealed to the body 22 to discourage and possibly prevent unauthorized access to the electrical device 400 covered by the cover assembly 10. To break the seal, a key or combination would be used to unlock the locking body 96. However as described above, in some embodiments, the seal member 86 may be an irreversible seal member where once sealed the seal member cannot be unsealed without cutting or otherwise breaking the seal member 86. Non-limiting examples of irreversible seal members 86 include meter-like tags, security seals, zip-ties and tie-wraps.

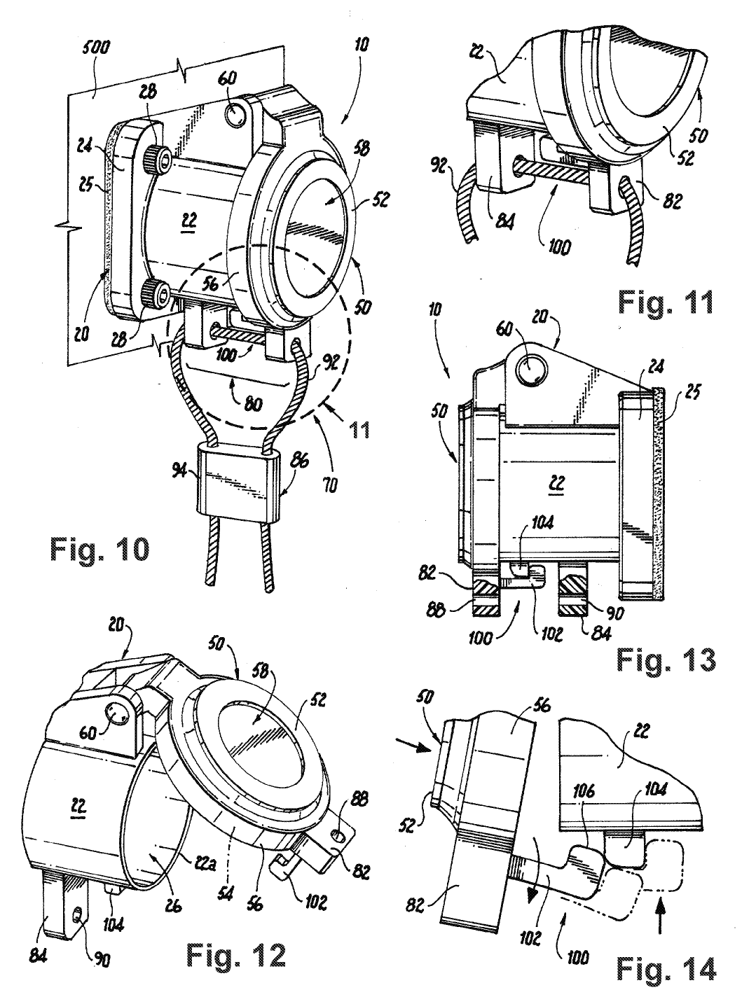

Referring now to FIGS. 10-14, another exemplary embodiment of a cover assembly 10 according to the present disclosure is shown. In this embodiment, the cover assembly 10 includes a housing 20, a lid 50 and a cover seal system 70, which are substantially the same as the housing, lid and cover seal system described in relation to FIGS. 2-5, except that the position of the second sealing tab 84 of the cover seal assembly 80 is moved to be further along on the body 22 to permit a clasp assembly 100 to be included with the cover assembly 10. The clasp assembly 100 is provided to clasp the lid 50 to the housing 20. The clasp assembly 100 may include a first member 102 that releasably engages a second member 104. In one exemplary embodiment, the clasp assembly 100 may be a snap-fit connection. Non-limiting examples of a snap-fit connections include, cantilever snap-fit and torsion snap-fit connections. In the embodiment shown, the snap-fit connection is a cantilever snap-fit connection, where the first member 102 is a cantilever arm or beam extending from the first sealing tab 82 or the lid 50 and the second member 104 is a shelf or catch extending from the body 22. For ease of description, the first member 102 may also be referred to herein as the “beam” and the second member 104 may also be referred to herein as the “catch.” The beam 102 can be integrally or monolithically formed to the first sealing tab 82 or the lid 50, or the beam 102 can be secured to the first sealing tab 82 or the lid 50 by, for example, welds, adhesives or other fasteners. The second member or catch 104 can be integrally or monolithically formed to the body 22, or the catch 104 can be secured to the body 22 by, for example, welds, adhesives or other fasteners. Preferably, the beam 102 extends from the first sealing tab 82 of the cover seal assembly 80, as shown in FIG. 13, allowing a user to exert a force, such as a pressing force, on the first sealing tab 82 in the direction of the catch 104. When the beam 102 contacts the catch 104, further force on the first sealing tab 82 causes the beam 102 to flex away from the body 22, seen in FIG. 14, so that the hook 106 of the beam 102 passes over the catch 104. When the hook 106 passes the catch 104, the beam 102 snaps back to its original steady state, as shown in FIG. 13, so that the hook 106 engages the catch 104 to hold the lid 50 in the closed position. When moving the lid 50 to the open position, the user first disengages the hook 106 of the beam 102 from the catch 104 by applying a force on the hook 106 away from the body 22 in order to release the hook 106 from the catch 104. The lid 50 can now be moved to the opened position. It is contemplated that the beam 102 may be located anywhere along the lid 50 and the catch 104 may be located anywhere along the body 22 so long as the beam 102 is aligned with the catch 104 when the lid 50 is in the closed position.

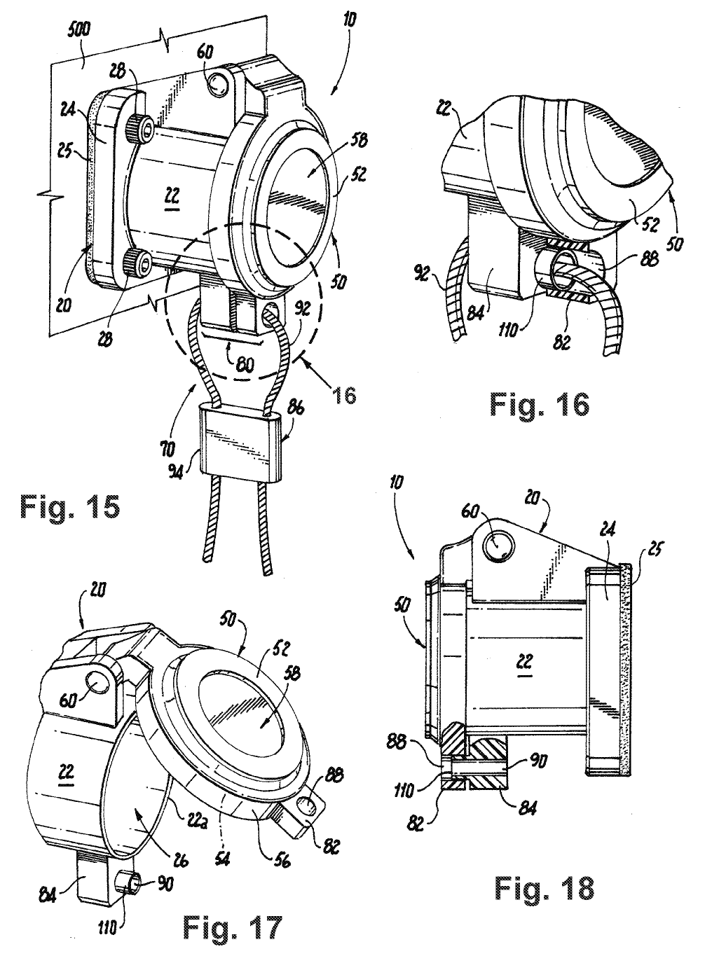

Referring now to FIGS. 15-18, another exemplary embodiment of a cover assembly 10 according to the present disclosure is shown. In this embodiment, the cover assembly 10 includes a housing 20, a lid 50, and a cover seal system 70. The housing 20 and lid 50 are substantially the same as the housing and lid described in relation to FIGS. 2-5 and are not repeated. In this exemplary embodiment, the cover seal assembly 80 of the cover seal system 70 differs from the previously described cover seal assemblies. More specifically, the shape and dimensions of the sealing tabs 82 and 84 of the cover seal assembly 80 differ. In this embodiment, to ensure alignment of the aperture 88 with the aperture 90 when the lid 50 is moved to the closed position, the second sealing tab 84 may include a projection 110, e.g., a tubular projection, extending therefrom that is configured to be received in the aperture 88 of the first sealing tab 82. Preferably, the projection 110 is substantially hollow so that the shackle 92 of the seal member 86 can be passed therethrough.

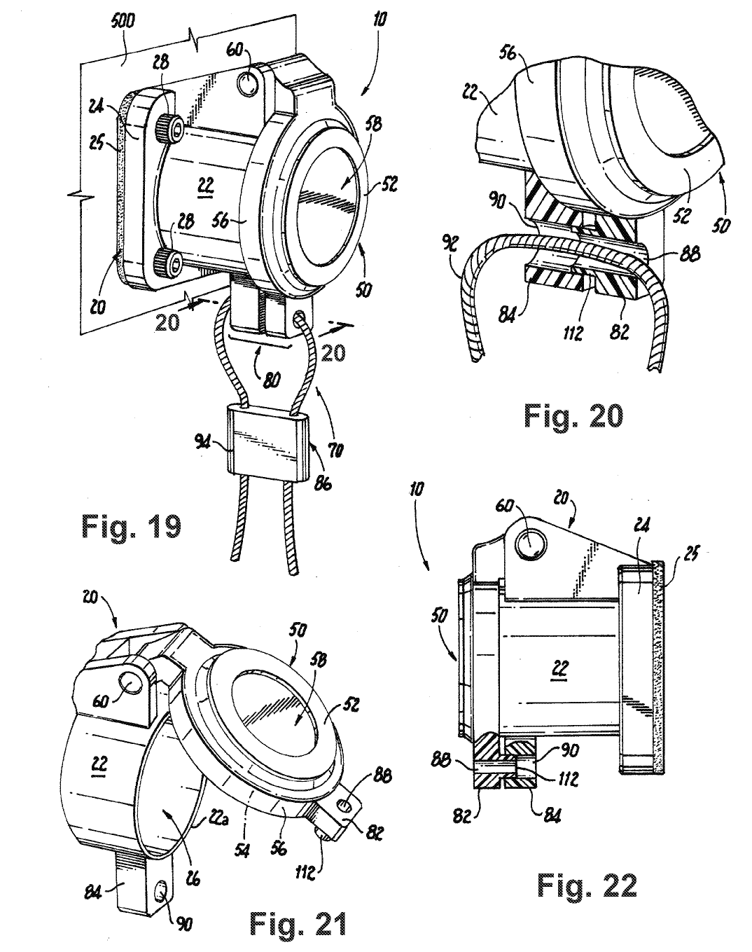

The embodiment of FIGS. 19-22 is substantially the same as the embodiment of FIGS. 15-18, except a tubular projection 112 extends from the first sealing tab 82 of the cover seal assembly 80 instead of the second sealing tab 84. As such, the tubular projection 112 is configured to be received in the aperture 90 of the second sealing tab 84 of the cover seal assembly 80. The projection 112 is substantially hollow so that the shackle 92 of the seal member 86 can be passed therethrough.

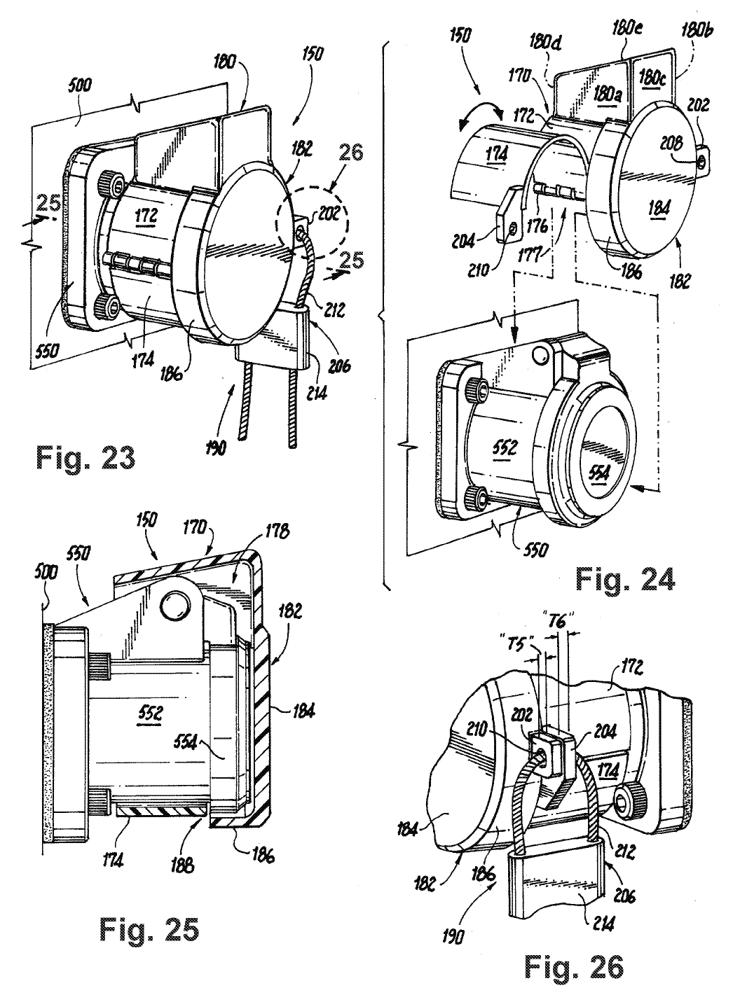

Referring now to FIGS. 23-26, an exemplary embodiment of a jacket assembly according to the present disclosure is shown. The jacket assembly 150 is configured to at least partially surround conventional cover assemblies 550 that cover at least the contact portion 402 of the electrical devices 400, seen in FIG. 1, and to couple with such conventional cover assemblies 550 in order to discourage and possibly prevent unauthorized access to the one or more electrical devices 400 covered by the conventional cover assemblies. The jacket assemblies 150 described herein may be made of materials that are sufficiently rigid to cover the conventional cover assemblies 550 or portions of the conventional cover assemblies 550 and to discourage and possibly prevent unauthorized access to the one or more electrical devices 400 covered by conventional cover assemblies 550. The jacket assemblies 150 described herein may also be made from materials that may further protect the conventional cover assemblies or portions of the conventional cover assemblies housed within the jacket assemblies 150 from environmental conditions, such as snow, rain, cold and heat. Preferably, the jacket assemblies 150 according to the present disclosure may be made of plastic materials or other non-conductive materials. Non-limiting examples of such plastic materials include thermoplastic materials or combinations of thermoplastic materials. Non-limiting examples of thermoplastic materials include Polycarbonate, Polybutylene Terephthalate (PBT) and Nylon. However, one skilled in the art would understand and appreciate that the jacket assemblies described herein can be made in other ways and from alternative materials without deviating from the scope contemplated by the present disclosure.

The jacket assemblies 150 include a jacket housing 170 and a jacket seal system 190. The jacket housing 170 is configured and dimensioned to fit onto and at least partially surround the body 552 and lid 554 of a conventional cover assembly 550. In the embodiment shown, the jacket housing 170 includes a jacket body 172 and a jacket lid 174. The jacket body 172 is an arcuate shaped structure, and the jacket lid 174 is an arcuate shaped structure. The jacket lid 174 is movably secured to the jacket body 172 by, for example, a hinge 176 so that the jacket lid 174 can move between a closed position where the free end of the jacket lid 174 can be sealed to the jacket body 172 and an open position where the jacket body 172 can be positioned or inserted onto the conventional cover assembly 550. Further, when the jacket lid 174 is in the closed position, the jacket body 172 and the jacket lid 174 form a cavity 177 configured to receive the body 552 of the conventional cover assembly 550, as shown in FIG. 24. The jacket housing 170 may also include a hinge receiving cavity 178, seen in FIG. 25, formed by one or more walls 180, seen in FIG. 23. The walls 180 include side walls 180a and 180b, end walls 180c and 180d, and top wall 180e. Preferably, the walls 180 are integrally or monolithically formed into the jacket body 172 so that the hinge receiving cavity 178 is in communication with the cavity 177 formed when the jacket lid 174 is sealed to the jacket body 172. The hinge receiving cavity 178 is configured and dimensioned to receive a hinge connecting the lid 554 to the body 552 of conventional cover assembly 550. The jacket housing 170 may also include a cap 182 configured and dimensioned to fit over the lid 554 of the conventional cover assembly 550. The cap 182 includes an exterior face 184 and an outer wall 186 extending from the face 184 and defining a cavity 188 to receive the lid 554 of the conventional cover assembly 550, as shown in FIG. 25.

Continuing to refer to FIGS. 23-26, the jacket seal system 190 of the jacket assembly 150 is configured to discourage and possibly prevent the lid 554 of conventional cover assemblies 550 from being moved to the open position and thus discourage and possibly prevent unauthorized access to the electrical device 400, seen in FIG. 1, or the contact portion 402 of the electrical device 400 within the conventional cover assembly 550. Further, the jacket seal system 190 may also provide evidence of tampering. In the embodiment shown in FIGS. 23-26, the jacket seal system 190 includes a jacket locking assembly 200 and at least one seal member or assembly 206. For ease of description, the at least one seal member or assembly 206 may also be referred to herein as the seal member 206 so that the present disclosure contemplates that the seal member 206 may be a member or an assembly.

The jacket locking assembly 200 includes a first sealing tab 202 and a second sealing tab 204. In the embodiment shown, the first sealing tab 202 is a solid member with a rectangular or square shaped cross-section that extends from the outer wall 186 of the cap 182 and includes an aperture 208 therethrough. The first sealing tab 202 may be integral with or monolithically formed into the outer wall 186, or the first sealing tab 202 may be secured to the outer wall 186 with for example welded joints or adhesives. The first sealing tab 202 has a predefined thickness “T5” that is sufficient to withstand accidental contact without breaking. In the embodiment shown, the predefined thickness “T5” of the first sealing tab 202 is smaller than the size of the outer wall 186 around the perimeter of the face 184 of the cap 182. The second sealing tab 204 is a solid member with an irregular shape that extends from the wall forming the jacket lid 174 and includes an aperture 210 therethrough. The second sealing tab 204 may be integral with or monolithically formed into the wall defining the jacket lid 174, or the second sealing tab 204 may be secured to the wall defining the jacket lid 174 with for example welded joints or adhesives. The second sealing tab 204 has a predefined thickness “T6” that is sufficient to withstand accidental contact without breaking. In the embodiment shown, the predefined thickness “T6” of the second sealing tab 204 is substantially the same as the thickness “T5” of the first sealing tab 202.

The first sealing tab 202 is positioned on the outer wall 186 of the cap 182 and the second sealing tab 204 is positioned on the wall forming the jacket lid 174 so that when the jacket lid 174 is in the closed position, the apertures 208 and 210 are in alignment with each other such that a portion of the seal member 206 can pass through the apertures 208 and 210 when sealing the jacket lid 174 to the cap 182. The seal member 206 is provided to seal the jacket lid 174 to the cap 182 of the housing assembly 170 to discourage and possibly prevent unauthorized access to the electrical device covered by conventional cover assembly 550. In this exemplary embodiment, the seal member 206 is an irreversible seal member where once sealed the seal member cannot be unsealed without cutting or otherwise breaking the seal member 206. Non-limiting examples of irreversible seal members 206 include meter-like tags, security seals, zip-ties and tie-wraps. An example of a security seal is the Cablelock 1.5 aluminum bodied cable seal, sold by American Casting and Manufacturing (https://seals.com/1-5-mm-barcoded-cable-seal-cablelock-1-5/). However, as described herein, the seal member 206 may be a reversable seal member that includes a locking body 214 having a locking mechanism with a key or combination that can be used to unlock the locking mechanism to break the seal. A non-limiting example of a seal member with a locking mechanism includes cable luggage locks. An example of a cable luggage lock is the Pack All, 3 Digit Combination TSA Padlock (https://www.packall.cc/products/packall-tsa-approved-cable-luggage-locks).

In the embodiment shown, the seal member 206 includes a shackle 212, e.g., a flexible cable or rigid bar, and an irreversible locking body 214. To seal the seal member 206 to the jacket assembly 150, one end of the shackle 212 is passed through the aperture 208 in the first sealing tab 202, through the aperture 210 in the second sealing tab 204 and through or at least partially into the locking body 214 so that the end of the shackle 212 can be locked in the locking body 214. In this configuration, the jacket lid 174 is sealed to the cap 182 to discourage and possibly prevent unauthorized access to the electrical device 400 covered by conventional cover 550. To break the seal, the shackle 212 would have to be cut. However, in some embodiments, the locking body of the seal member 206 may have locking mechanism, seen in FIG. 6, with a key or combination that can be used to unlock the locking mechanism so the shackle 212 can be removed from the locking body 214 to break the seal. A non-limiting example of a seal member 206 with a locking mechanism includes cable luggage locks. An example of a cable luggage lock is the Pack All, 3 Digit Combination TSA Padlock (https://www.packall.cc/products/packall-tsa-approved-cable-luggage-locks).

Continuing to refer to FIGS. 23-26, the attachment of the jacket assembly 150 to a conventional cover 550 will be described. As depicted in FIG. 24, the jacket lid 174 of the jacket housing 170 is moved to an open position providing access to the cavity 177, and the jacket body 172 is placed over conventional cover 550 so that the body 552 of the conventional cover 550 is within the cavity 177 and the cap 182 is positioned on the lid 554 of the conventional cover 550, as shown in FIG. 25. With the jacket body 172 on or over the body 552 of conventional cover 550, the jacket lid 174 of the jacket housing 170 is moved to the closed position, seen in FIG. 23, so that the jacket housing 170 surrounds the at least a portion of the body 552 and lid 554 of conventional cover 550, and so that the apertures 208 and 210 of the sealing tabs 202 and 204, respectively, are in alignment as shown in FIG. 26. With the apertures 208 and 210 of the sealing tabs 202 and 204 aligned, one end of the shackle 212 is passed through the aperture 208 in the first sealing tab 202, through the aperture 210 in the second sealing tab 204 and through or at least partially into the locking body 214 so that the end of the shackle 212 is locked in the locking body 214. In this configuration, the jacket lid 174 is sealed to the cap 182 of the jacket housing 170 to discourage and possibly prevent unauthorized access to the electrical device 400 covered by the conventional cover 550. To break the seal, the shackle 212 would have to be cut. However, in some embodiments, the locking body of the seal member 206 may have locking mechanism with a key or combination that can be used to unlock the locking mechanism so the shackle 212 can be removed from the locking body 214 to break the seal. A non-limiting example of a seal member with a locking body having a locking mechanism includes cable luggage locks. An example of a cable luggage lock is the Pack All, 3 Digit Combination TSA Padlock (https://www.packall.cc/products/packall-tsa-approved-cable-luggage-locks).

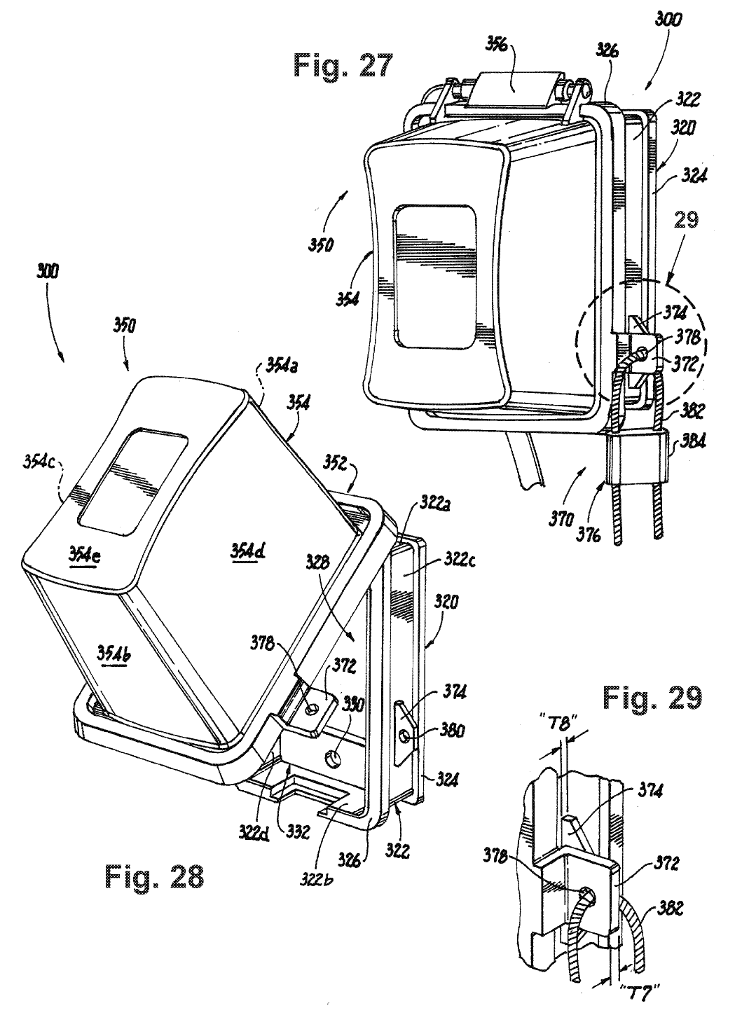

Turning now to FIGS. 27-29, another exemplary embodiment of a cover assembly according to the present disclosure is shown. In this exemplary embodiment, the cover assembly 300 is configured and dimensioned to mount to an electrical box and to cover electrical devices such as electrical receptacles, electrical switches and other wiring devices within the electrical box (not shown). In this embodiment, the cover assembly 300 includes a housing 320, a lid 350, and a cover seal assembly 370. The housing 320 includes a body 322 between a mounting flange 324 and a cover flange 326. The body 322 is defined by walls 322a, 322b, 322c and 322d that extend from the mounting flange 324 to the cover flange 326. The body 322 may be integrally or monolithically formed into the flanges 324 and 326, or the body 322 may be secured to the flanges 324 and 326 by, for example, welded joints, adhesives or fasteners. The mounting flange 324 is a substantially rectangular member having an opening 328 configured to receive a cover portion of the electrical device, and one or more mounting holes 330 used to secure the cover assembly 300 to the electrical box (not shown) supporting the electrical device. In the embodiment shown, the housing body 322 is a substantially rectangular body having a rectangular opening 332 that is in communication with the mounting flange opening 328 and provides access to the cover portion of the electrical device. However, it is contemplated the shape of the body 322, mounting flange 324 and cover flange 326 may be any shape sufficient to at least partially surround and provide access to at least a portion of the electrical device 400. For example, the shape of the body 322, mounting flange 324 and cover flange 326 may be any number of polygonal and non-polygonal shapes, including, for example, hexagonal and circular shapes. In the embodiment shown, the mounting flange 324 is substantially planar and configured to be attached to the electrical box (not shown). A seal member (not shown), e.g., a gasket, may be positioned between the mounting flange 324 and the electrical box to seal the flange opening 328 and thus the electrical device.

In this exemplary embodiment, the lid 350 includes a lid flange 352 and a lid body 354. The lid flange 352 is configured to receive the cover flange 326 when the lid 350 is in a closed position shown in FIG. 27. The lid flange 352 is rectangular shaped flanged with an open center. The lid body 354, which is defined by walls 354a, 354b, 354c, 354d and 354e, extends from the lid flange 352 to form a cavity that, for example, covers a power cord plugged into an electrical receptacle. The lid flange 352 is movably, e.g., pivotably, attached to the body 322 by a hinge 356 so that the lid 350 moves between an open position, seen in FIG. 28, and the closed position, see in FIG. 27.

Continuing to refer to FIGS. 27-29, the cover seal assembly 370 of the cover assembly 300 is configured to discourage and possibly prevent the lid 350 of the cover assembly 300 from being moved to the open position and thus discourage and possibly prevent unauthorized access to the electrical device or the portion of the electrical device within the cover assembly 300. Further, the cover seal assembly 370 may also provide evidence of tampering. In the embodiment shown, the cover seal assembly 370 includes a first sealing tab 372, a second sealing tab 374 and a seal member or assembly 376. For ease of description, the seal member or assembly 376 may also be collectively referred to herein as the seal member 376 so that the present disclosure contemplates that the seal member 376 may be a member or an assembly. In the embodiment shown, the first sealing tab 372 is a solid member with a rectangular or square shaped cross-section that extends from the outer wall of the lid flange 352 and includes an aperture 378 therethrough. The first sealing tab 372 may be integral with or monolithically formed into the lid flange 352, or the first sealing tab 372 may be secured to the outer wall of the lid flange 352 with for example welded joints or adhesives. The first sealing tab 372 has a predefined thickness “T7” that is sufficient to withstand accidental contact without breaking. In the embodiment shown, the predefined thickness “T7” of the first sealing tab 372 is smaller than the size of the outer wall of the lid flange 352. The second sealing tab 374 is a solid member with an irregular shape that extends from the wall 322c of the body 322 and includes an aperture 380 therethrough. The second sealing tab 374 may be integral with or monolithically formed into the wall 322c of the body 322, or the second sealing tab 374 may be secured to the wall 322c of the body 322 with for example welded joints or adhesives. The second sealing tab 374 has a predefined thickness “T8” that is sufficient to withstand accidental contact without breaking. In the embodiment shown, the predefined thickness “T8” of the second sealing tab 374 is substantially the same as the thickness “T7” of the first sealing tab 372.

The first sealing tab 372 is positioned on the outer wall of the lid flange 352 and the second sealing tab 374 is positioned on the wall 322c of the body 322 so that when the lid 354 is in the closed position, the apertures 378 and 380 are in alignment with each other such that a portion of the seal member 376 can pass through the apertures 378 and 380 when sealing the lid 350 to the housing 320. The seal member 376 is provided to seal the lid 350 to the housing 320 to discourage and possibly prevent unauthorized access to the electrical device 400 covered by the cover assembly 300. In this exemplary embodiment, the seal member 376 is an irreversible seal member where once sealed the seal member cannot be unsealed without cutting or otherwise breaking the seal member 376. Non-limiting examples of irreversible seal members 376 include meter-like tags, security seals, zip-ties and tie-wraps. An example of a security seal is the Cablelock 1.5 aluminum bodied cable seal, sold by American Casting and Manufacturing (https://seals.com/1-5-mm-barcoded-cable-seal-cablelock-1-5/). In the embodiment shown, the seal member 376 includes a shackle 382, e.g., a flexible cable or rigid bar, and an irreversible locking body 384. To seal the seal member 376 to the cover assembly 300, one end of the shackle 382 is passed through the aperture 378 in the first sealing tab 372, through the aperture 380 in the second sealing tab 374 and through or at least partially into the locking body 384 so that the end of the shackle 382 can be locked in the locking body 384. In this configuration, the lid 350 is sealed to the body 322 to discourage and possibly prevent unauthorized access to the electrical device 400 covered by the cover assembly 300. To break the seal, the shackle 382 would have to be cut. However, in some embodiments, the locking body of the seal member 376 may have locking mechanism, seen in FIG. 6, with a key or combination that can be used to unlock the locking mechanism and break the seal. A non-limiting example of a seal member with a locking mechanism includes cable luggage locks. An example of a cable luggage lock is the Pack All, 3 Digit Combination TSA Padlock (https://www.packall.cc/products/packall-tsa-approved-cable-luggage-locks).

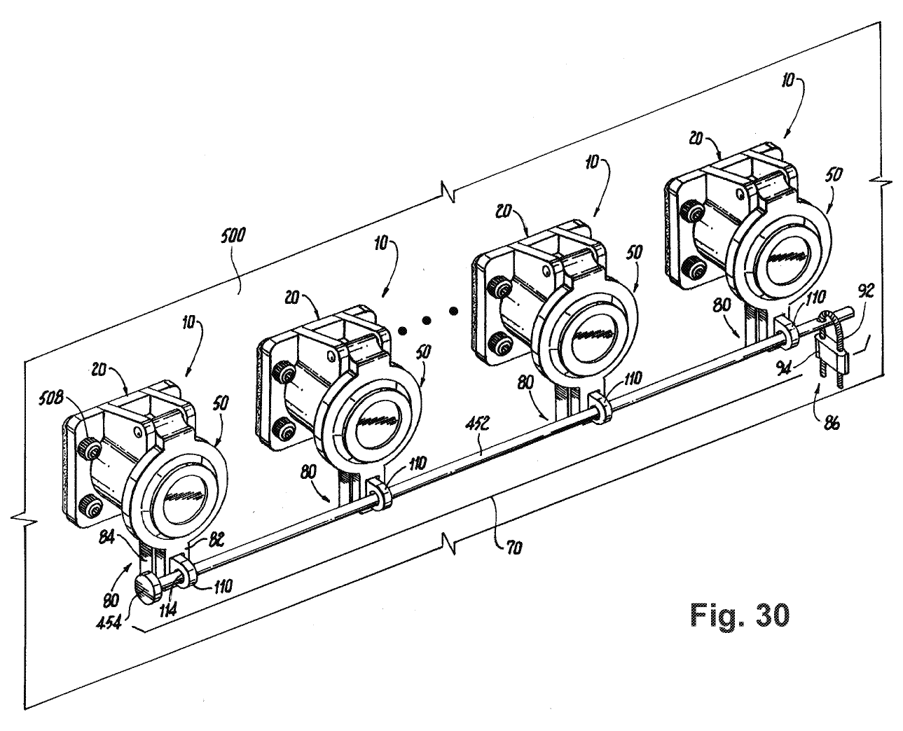

FIGS. 30-41 depicts a plurality of cover assemblies 10 according to the present disclosure mounted to a structure 500. Each cover assembly 10 includes a housing 20, a lid 50 and at least a portion of a cover seal system 70. The cover assembly 10 according to this exemplary embodiment is configured to discourage and possibly prevent the lid 50 from being moved to the open position and thus discourage and possibly prevent unauthorized access to the electrical device 400, seen in FIG. 1, or the portion of the electrical device within the cover assembly. Further, the cover seal system 70 may also provide evidence of tampering. In this embodiment, the housing 20 and lid 50 are substantially the same as the housing and lid described herein and are not repeated. However, in this exemplary embodiment, the cover seal system 70 differs. In this exemplary embodiment, the cover seal system 70 includes a plurality of cover seal assemblies 80, an interlocking member or assembly 450 and a seal member 86, seen in FIG. 2, configured and dimensioned to discourage and possibly prevent the lids 50 of a plurality of cover assemblies 10 from being moved to the open position.

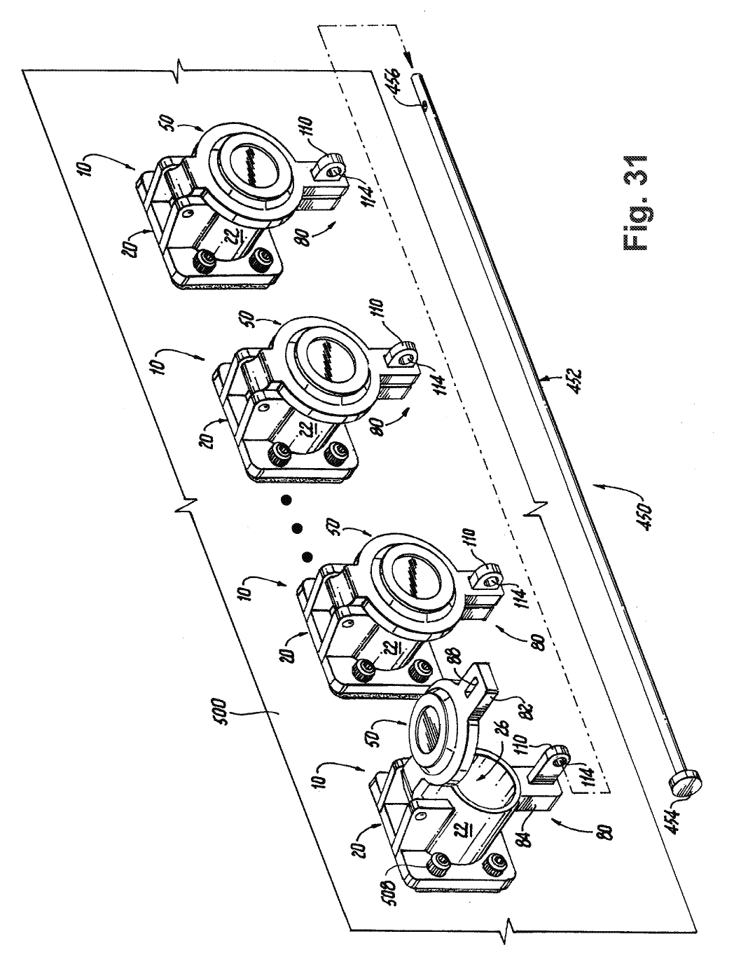

Each cover seal assembly 80 includes a first sealing tab 82 that has a slot as the aperture 88, and a second sealing tab 84 that has a ridge or rib as the projection 110. The rib 110 extends from the second sealing tab 84 and may be integrally or monolithically formed into the second sealing tab 84. The rib 110 is configured and dimensioned to pass through the slot 88, seen in FIG. 31, in the first sealing tab 82. The rib 110 includes an aperture 114 that is configured and dimensioned to interact with at least a portion of the interlocking member or assembly 450 used when sealing the lids 50 of the cover assemblies 10 to the housings 20 of the cover assemblies 10. For ease of description, the interlocking member or assembly 450 may also be referred to herein as the interlocking member 450 so that the present disclosure contemplates that the interlocking member 450 may be a member or an assembly. In some embodiments, the interlocking member 450 may include a shaft, rod, wire or cable or other member 452. For ease of description, the shaft, rod, wire or cable or other member 452 may also be referred to herein as the shaft 452. Further, the shaft 452 may be identified in the figures with alphanumeric characters such as 452a, 452b and 452c, to identify different shafts, rods, wires or cables or other members. In other embodiments, the interlocking member 450 may include an assembly that has an inner rod 460 so that the present disclosure contemplates that the interlocking member 450 may be a member or an assembly.

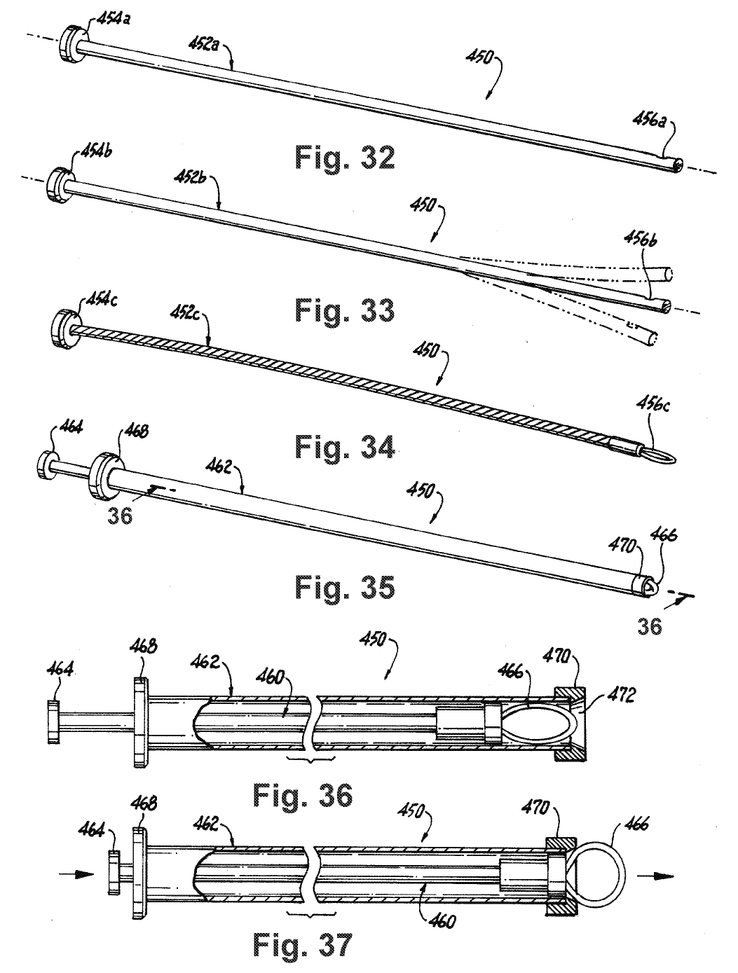

In the embodiment of FIG. 30-32, the interlocking member 450 includes a shaft 452a, seen in FIG. 32, that is preferably an elongated shaft, rod or member that can be passed through the apertures 114 of the plurality of cover seal assemblies 80 so that a single interlocking member 450 can be used to seal the lids 50 to the housings 20 of a plurality of cover assemblies 10 and thus seal the lids 50 of each of the plurality of cover assemblies 10 in the closed position, as shown. The shaft 452a may be a solid shaft or a hollow shaft that includes a handle 454a, e.g., a thumb knob, at a proximal end and an aperture 456a at a distal end. In this embodiment, the shaft 452a is a rigid shaft that can be made of a metallic material, e.g., stainless steel or galvanized steel, or the shaft 452a can be made of a rigid plastic material, e.g., Acetal/Delrin^{®} rods, Nylon^{®} rods, Teflon^{®} PTFE rods and PVC Rods. As described above, the seal member 86 is used to seal the interlocking member 450 to the cover assemblies 10 and may include a shackle 92, e.g., a flexible cable or rigid bar, that can be locked in an irreversible locking body 94, seen in FIG. 30. The shackle 92 is passed through the aperture 456a in the shaft 452a and is locked to the irreversible locking body 94 to seal each lid 50 of each of the plurality of cover assemblies 10 in the closed position. In some embodiments, the locking body 94 of the seal member 86 may have locking mechanism with a key or combination that can be used to unlock the locking mechanism so the shackle 92 can be removed from the locking body 94 to break the seal.

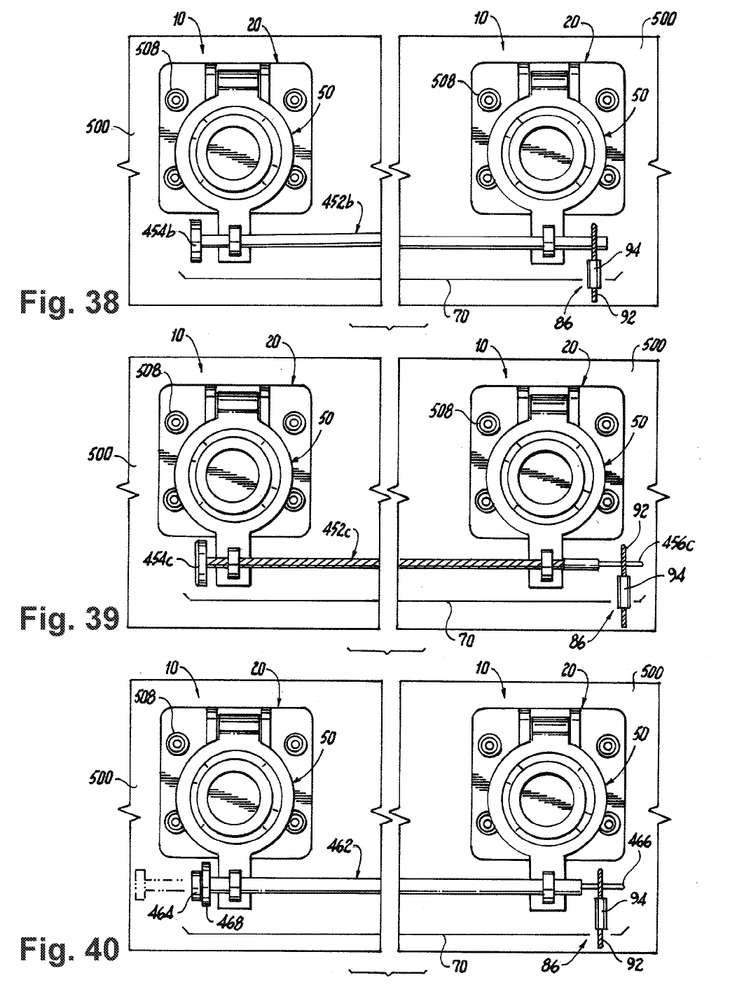

There may be instances where the cover assemblies 10 are not precisely aligned on the structure such that there may be an offset “O” in the alignment of the cover assemblies 10 and thus an offset “O” in the apertures 114 of the cover seal assemblies 80, as shown in FIG. 41. In such instances, it is preferred that the interlocking member 450 can flex so that the interlocking member 450 can be passed through each cover seal assembly 80 of each cover assembly 10 mounted to the structure 500. More specifically, the flexible interlocking member 450 permits a single interlocking member 450 to seal the plurality of cover assemblies 10 even if they are not precisely aligned. In the embodiment of FIG. 33, the interlocking member 450 includes a shaft 452b that is preferably an elongated flexible or semi-flexible shaft, rod or member 452b that can be passed through the apertures 114 of the plurality of cover seal assemblies 80 of the plurality of cover assemblies 10 so that a single interlocking member 450 can be used to seal the plurality of cover assemblies 10, as shown in FIG. 41. The shaft 452b may be a solid shaft or a hollow shaft, and includes a handle 454b, e.g., a thumb knob, at a proximal end, and an aperture 456b at a distal end. In this embodiment, the flexible or semi-flexible shaft 452b can be made of a metallic material, e.g., spring steel, shape memory alloys, flexible metal hoses, or the shaft 452b can be made of a flexible or semi-flexible plastic material, e.g., thermoplastic elastomers (TPE) or high-density polyethylene (HDPE). As described above, the seal member 86 used to seal the interlocking member 450 to the cover assemblies 10 may include a shackle 92 that can be locked in an irreversible locking body 94, seen in FIGS. 38 and 41. The shackle 92 is passed through the aperture 456b in the shaft 452b and is locked to the irreversible locking body 94 to seal each lid 50 of each of the plurality of cover assemblies 10 in the closed position. In some embodiments, the locking body 94 of the seal member 86 may have locking mechanism with a key or combination that can be used to unlock the locking mechanism so the shackle 92 can be removed from the locking body 94 to break the seal.

Similar to the embodiment of FIG. 33, FIG. 34 depicts an interlocking member 450 includes an elongated flexible member 452c, such as a wire cable, as the shaft that can be passed through each cover seal assembly 80 of each cover assembly 10 mounted to the structure 500 so that the flexible member 452c permits a single interlocking member 450 to seal the plurality of cover assemblies 10. The shaft 452c, i.e., the flexible member, includes a handle 454c, e.g., a thumb knob, at a proximal end, and an eyelet 456c is secured or attached to a distal end. The eyelet 456c is preferably flexible so that the eyelet 456c can be passed through the aperture 114 of the plurality of cover seal assemblies 80 of the plurality of cover assemblies 10. As described above, the seal member 86 used to seal the interlocking member 450 to the cover assemblies 10 may include a shackle 92 that can be locked in an irreversible locking body 94, seen in FIG. 39. The shackle 92 is passed through the eyelet 456c in the flexible member 452c and is locked to the irreversible locking body 94 to seal each lid 50 of each of the plurality of cover assemblies 10 in the closed position. In some embodiments, the locking body 94 of the seal member 86 may have locking mechanism with a key or combination that can be used to unlock the locking mechanism so the shackle 92 can be removed from the locking body 94 to break the seal.

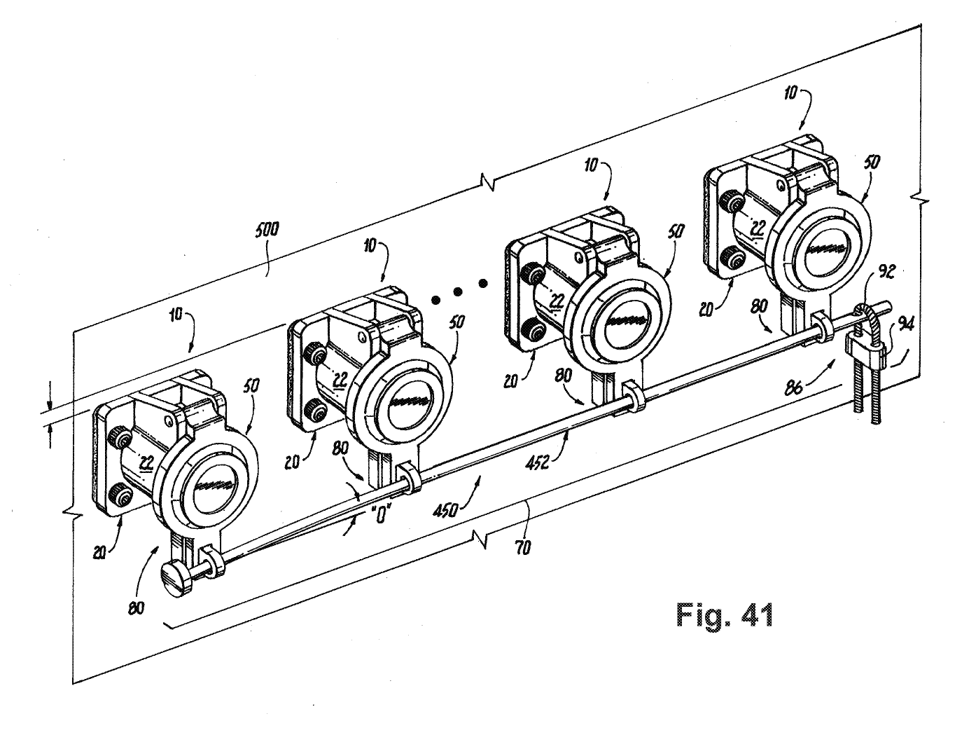

In the embodiment of FIGS. 35-37, the interlocking member 450 is a telescopic structure that includes an inner shaft, rod or other member 460 and an outer hollow member 462, e.g., a tubular member. For ease of description, the inner shaft, rod or member 460 may be referred to as the inner rod 460. The inner rod 460 is positioned within the outer hollow member 462 so that the inner rod 460 is movable within the outer hollow member 462 between a loaded position, seen in FIG. 36, and a deployed position, seen in FIG. 37. The inner rod 460 may be a solid shaft or rod or a hollow shaft or rod, and includes a handle 464, e.g., a thumb knob, at a proximal end, and an eyelet 466 secured to, integral with or monolithically formed into a distal end of the inner rod 460. In this embodiment, the inner rod 460 may be a rigid member, a flexible member or a semi-flexible member. The outer hollow member 462 includes a first cap 468 at a proximal end and a second cap 470 at a distal end. The first cap 468 and the second cap 470 block the inner rod 460 from being removed from the outer hollow member 462 as the inner rod 460 moves within the outer hollow member 462. The first cap 468 includes an aperture (not shown) that permits a portion of the inner rod 460 to extend out of the outer hollow member 462, as shown. The second cap 470 includes an aperture 472, seen in FIG. 36, that permits the eyelet 466 at the distal end of the inner rod 460 to be received within the outer hollow member 462 when the inner rod 460 is in the loaded position, and that permits the eyelet 466 to extend from the distal end of the outer hollow member 462. In this embodiment, the outer hollow member 462 may be a rigid member, a flexible member or a semi-flexible member. The eyelet 466 is preferably flexible so that the eyelet 466 can be passed through the aperture 472 in the second cap 470 when the inner rod 460 is moved to the loaded position, and so that when the inner rod 460 is moved to the deployed position, the eyelet 466 can pass through the aperture 472 and extend out of the second cap 470 of the outer hollow member 462. As described above, the seal member 86 used to seal the interlocking member 450 to the cover assemblies 10 may include a shackle 92 that can be locked in an irreversible locking body 94, seen in FIG. 40. The shackle 92 is passed through the eyelet 466 at the distal end of the inner rod 460 when the inner rod 460 is in the deployed position, and is locked to the irreversible locking body 94 to seal each lid 50 of each of the plurality of cover assemblies 10 in the closed position. In some embodiments, the locking body 94 of the seal member 86 may have locking mechanism with a key or combination that can be used to unlock the locking mechanism so the shackle 92 can be removed from the locking body 94 to break the seal.

It is noted that in the embodiment of FIG. 35-37, the inner rod 460 and the outer hollow member 462 can be made of a metallic material, e.g., stainless steel, aluminium, spring steel, shape memory alloys, flexible metal hoses, or the inner rod 460 and the outer hollow member 462 can be made of a flexible or semi-flexible plastic material, e.g., thermoplastic elastomers (TPE) or high-density polyethylene (HDPE).

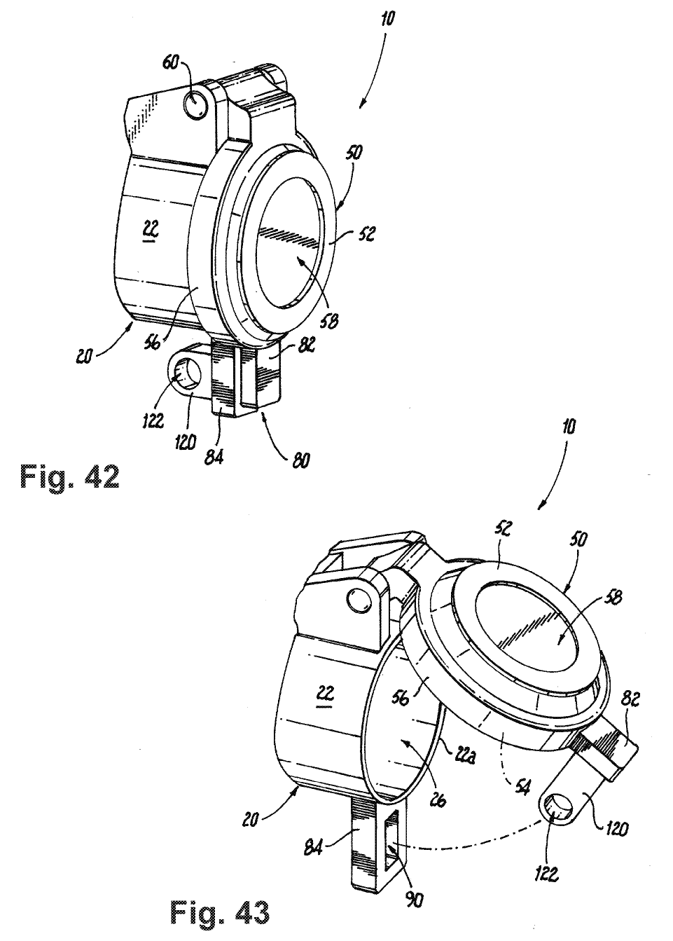

Another exemplary embodiment of a cover assembly 10 according to the present disclosure is shown in FIGS. 42-46. In this embodiment, the cover assembly 10 includes a housing 20, a lid 50, and a cover seal system 70. The housing 20 and lid 50 are substantially the same as the housing and lid described herein and are not repeated. The cover seal system 70 includes a plurality of cover seal assemblies 80, an interlocking member or assembly 450 and a seal member 86 configured and dimensioned to discourage and possibly prevent the lids 50 of a plurality of cover assemblies 10 from being moved to the open position and thus discourage and possibly prevent unauthorized access to the electrical devices 400 or the portion of the electrical devices 400 within the plurality of cover assemblies 10. Further, the cover seal system 70 may also provide evidence of tampering. In this exemplary embodiment, the interlocking member or assembly 450 and a seal member 86 are substantially the same as the interlocking member 450 and a seal member 86 described herein and are not repeated. For ease of description, the interlocking member or assembly 450 may also be referred to herein as the interlocking member 450 so that the present disclosure contemplates that the interlocking member 450 may be a member or an assembly.

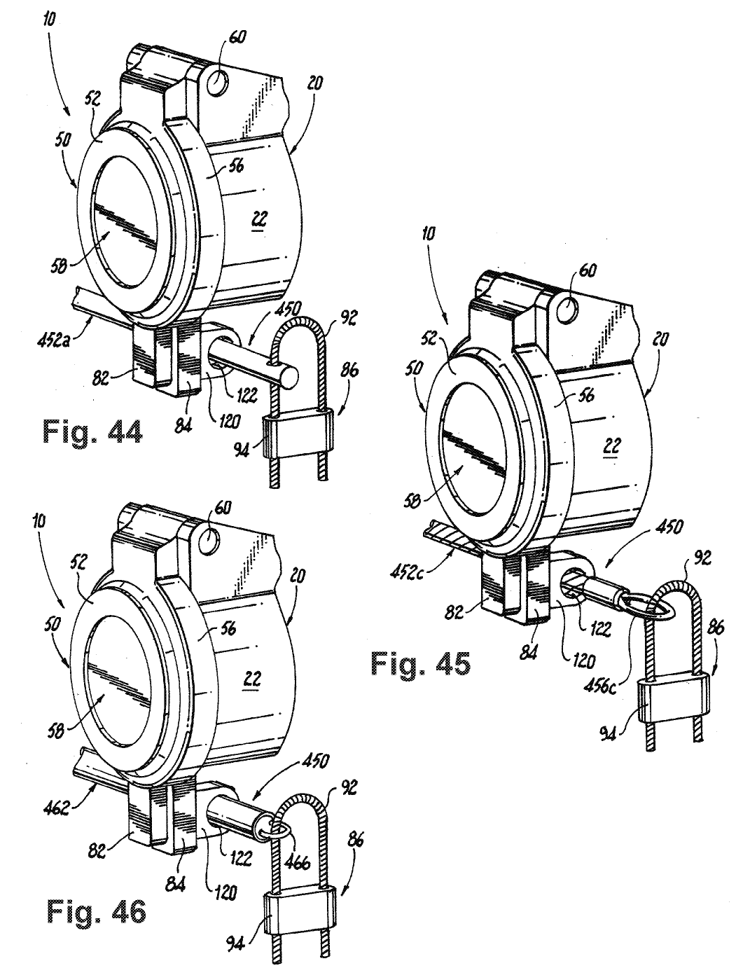

In this exemplary embodiment, the cover seal assemblies 80 differ. More specifically, each cover seal assembly 80 includes a first sealing tab 82 that has a ridge or rib as a projection 120. The rib 120 extends from the first sealing tab 82 and may be integrally or monolithically formed into the first sealing tab 82. The rib 120 is configured and dimensioned to pass through a slot as the aperture 90, seen in FIG. 43, extending through the second sealing tab 84. The rib 120 includes an aperture 122 that is configured and dimensioned to interact with at least a portion of the interlocking member 450 used when sealing the lids 50 of the cover assemblies 10 to the housings 20 of the cover assemblies 10. As shown FIG. 44, the interlocking member 450 of the cover seal system 70 may include the shaft 452a or shaft 452b which can then be passed through the apertures 122 of the cover seal assemblies 80 for all or a portion of the cover assemblies 10 attached to the structure 500, seen in FIGS. 30 and 31. The portion of the interlocking member 450 shown in FIG. 44 is inserted through the aperture 122 in the rib 120 extending from the first sealing tab 82 of the last cover assembly 10 on the structure 500. As described herein, the seal member 86 used to seal the interlocking member 450 to the cover assemblies 10 may include a shackle 92 that can be locked in a locking body 94, seen in FIG. 44. The shackle 92 is passed through the aperture 456a or 456b, seen in FIGS. 32 and 33, at the distal end of the shaft 452a or 452b and is locked to the locking body 94 to seal each lid 50 of each of the plurality of cover assemblies 10 in the closed position. As seen FIG. 45, the interlocking member 450 of the cover seal system 70 may include the shaft 452c, seen in FIG. 34, which can then be passed through the apertures 122 of the cover seal assemblies 80 for all or a portion of the cover assemblies 10 attached to the structure 500. The portion of the interlocking member 450 shown in FIG. 45 is inserted through the aperture 122 in the rib 120 extending from the first sealing tab 82 of the last cover assembly 10 on the structure 500. As described herein, the seal member 86 used to seal the interlocking member 450 to the cover assemblies 10 may include a shackle 92 that can be locked in an irreversible locking body 94, seen in FIG. 45. The shackle 92 is passed through the eyelet 456c at the distal end of the flexible member 452c and is locked to the locking body 94 to seal each lid 50 of each of the plurality of cover assemblies 10 in the closed position. In some embodiments, the locking body 94 of the seal member 86 may have locking mechanism with a key or combination that can be used to unlock the locking mechanism so the shackle 92 can be removed from the locking body 94 to break the seal. As seen FIG. 46, the interlocking member 450 of the cover seal system 70 may be the telescopic structure, described herein and shown in FIGS. 35-37, that includes an inner shaft, rod or other member 460 and an outer hollow member 462, e.g., a tubular member. The outer hollow member 462 and thus the inner rod 460 can be passed through the apertures 122 of the cover seal assemblies 80 for all or a portion of the cover assemblies 10 attached to the structure 500. The portion of the interlocking member 450 shown in FIG. 46 is inserted through the aperture 122 in the rib 120 extending from the first sealing tab 82 of the last cover assembly 10 on the structure 500. As described herein, the seal member 86 used to seal the interlocking member 450 to the cover assemblies 10 may include a shackle 92 that can be locked in an irreversible locking body 94, seen in FIG. 46. The shackle 92 is passed through the eyelet 466 at the distal end of the inner rod 460 and is locked to the irreversible locking body 94 to seal each lid 50 of each of the plurality of cover assemblies 10 in the closed position. In some embodiments, the locking body 94 of the seal member 86 may have locking mechanism with a key or combination that can be used to unlock the locking mechanism so the shackle 92 can be removed from the locking body 94 to break the seal.

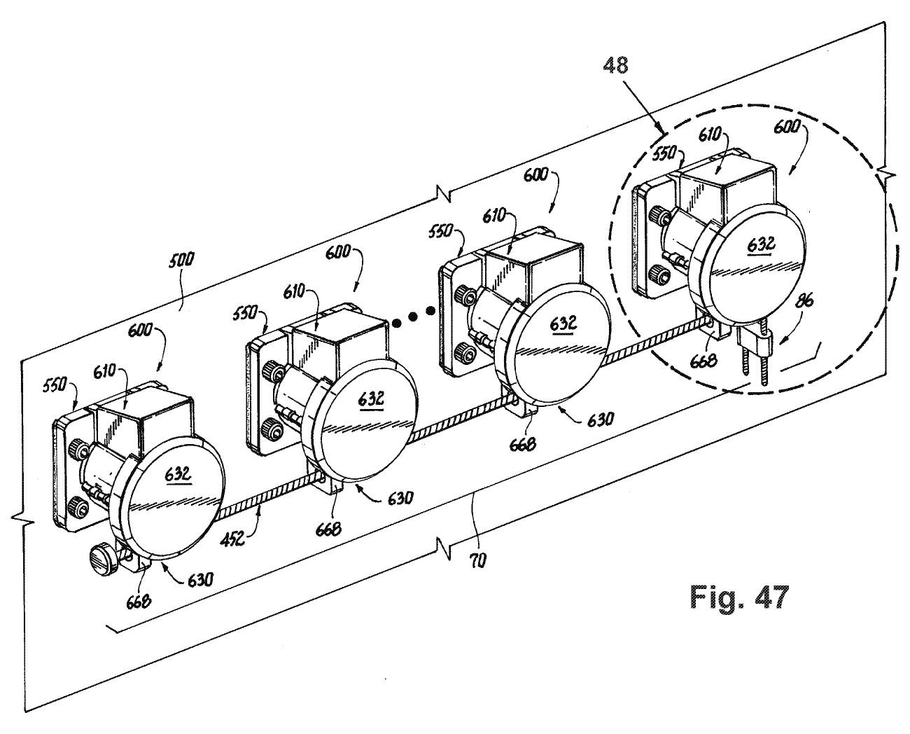

Turning now to FIG. 47, a plurality of conventional cover assemblies 550 mounted to a structure 500 and a corresponding plurality of jacket assemblies 600 configured and dimensioned to fit onto and at least partially surround the body 552 and lid 554, seen in FIG. 50, of the conventional cover assemblies 550 are shown. The interlocking member 450 described herein interacts with a jacket seal system 650 associated with each of the plurality of jacket assemblies 600 to seal each jacket body 620 to a jacket lid 640 of each jacket housing 610 so that the lid 554 of each conventional cover assembly 550 is sealed in the closed position.

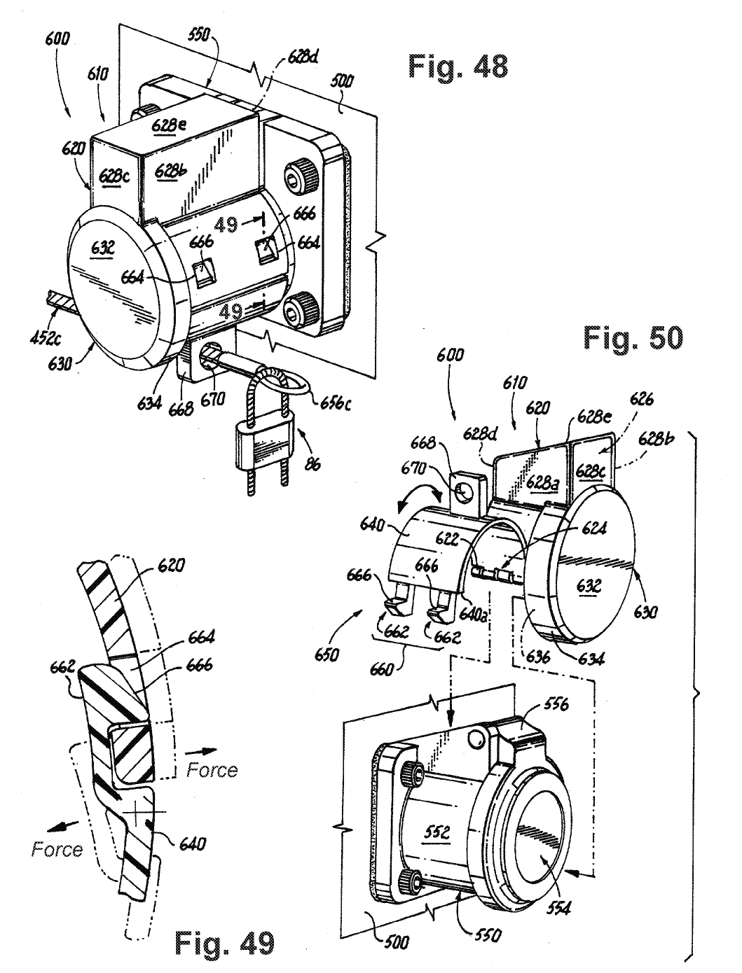

Referring now to FIGS. 48-53, the exemplary embodiment of the jacket assembly 600 is shown. The jacket assembly 600 is configured to at least partially surround conventional cover assemblies 550 that cover at least the contact portion 402 of the electrical devices 400, seen in FIG. 1, and to couple with such conventional cover assemblies 550 in order to discourage and possibly prevent unauthorized access to the one or more electrical devices 400 covered by the conventional cover assemblies 550. The jacket assemblies 600 described herein may be made of materials that are sufficiently rigid to cover the conventional cover assemblies 550 or portions of the conventional cover assemblies 550 and to discourage and possibly prevent unauthorized access to the one or more electrical devices 400 covered by conventional cover assemblies 550. The jacket assemblies 600 described herein may also be made from materials that may further protect the conventional cover assemblies or portions of the conventional cover assemblies 550 housed within the jacket assemblies 600 from environmental conditions, such as snow, rain, cold and heat. Preferably, the jacket assemblies 600 according to the present disclosure may be made of plastic materials or other non-conductive materials. Non-limiting examples of such plastic materials include thermoplastic materials or combinations of thermoplastic materials. Non-limiting examples of thermoplastic materials include Polycarbonate, Polybutylene Terephthalate (PBT) and Nylon. However, one skilled in the art would understand and appreciate that the jacket assemblies described herein can be made in other ways and from alternative materials without deviating from the scope contemplated by the present disclosure.

The jacket assemblies 600 include a jacket housing 610 and a jacket seal system 650. The jacket housing 610 is configured and dimensioned to fit onto and at least partially surround the body 552 and lid 554 of a conventional cover assembly 550. In the embodiment shown, the jacket housing 610 includes a jacket body 620 and a jacket lid 640. The jacket body 620 is at least partially an arcuate shaped structure, and the jacket lid 640 is an arcuate shaped structure. The jacket lid 640 is movably secured to the jacket body 620 by, for example, a hinge 622 so that the jacket lid 640 can move between a closed position and an open position. In the closed position the free end of the jacket lid 640 can be sealed to the jacket body 620, and in the open position the jacket body 620 can be positioned or inserted onto the conventional cover assembly 550. Further, when the jacket lid 640 is in the closed position, the jacket body 620 and the jacket lid 640 form a cavity 624 configured to receive the body 552 of the conventional cover assembly 550, as shown in FIG. 50. The jacket housing 610 may also include a hinge receiving cavity 626, seen in phantom in FIG. 50, formed by one or more walls 628. The hinge receiving cavity 626 is similar to the hinge receiving cavity 178 described herein and shown in FIG. 25. The walls 628 include side walls 628a and 628b, end walls 628c and 628d, and top wall 628e. Preferably, the walls 628 are integrally or monolithically formed into the jacket body 620 so that the hinge receiving cavity 626 is in communication with the cavity 624 formed when the jacket lid 640 is sealed to the jacket body 620. The hinge receiving cavity 626 is configured and dimensioned to receive a hinge 556 connecting the lid 554 to the body 552 of conventional cover assembly 550. The jacket housing 610 may also include a cap 630 configured and dimensioned to fit over the lid 554 of the conventional cover assembly 550. The cap 630 includes an exterior face 632 and an outer wall 634 extending from the face 632 and defining a cavity 636 to receive the lid 554 of the conventional cover assembly 550, as shown in FIG. 50.

Continuing to refer to FIGS. 48-50, the jacket seal system 650 of the jacket assembly 600 is configured to discourage and possibly prevent the lid 554 of conventional cover assemblies 550 from being moved to the open position and thus discourage and possibly prevent unauthorized access to the electrical device 400 or the contact portion 402 of the electrical device 400 within the conventional cover assembly 550. Further, the jacket seal system 650 may also provide evidence of tampering. In the embodiment shown in FIGS. 48-50, the jacket seal system 650 includes a plurality of jacket locking assemblies 660, an interlocking member or assembly 450 and a seal member or assembly 86. The plurality of jacket locking assemblies 660, interlocking member 450 and seal member 86 are configured and dimensioned to discourage and possibly prevent the lids 554 of a plurality of conventional cover assemblies 550 from being moved to the open position and thus discourage and possibly prevent unauthorized access to the electrical devices 400 or the portion of the electrical devices 400 within the plurality of conventional cover assemblies 550. For ease of description, the interlocking member or assembly 450 may also be referred to herein as the interlocking member 450 so that the present disclosure contemplates that the interlocking member 450 may be a member or an assembly. The interlocking member 450 is described herein such that a description thereof is not repeated. In addition, the seal member or assembly 86 may also be referred to herein as the seal member 86 so that the present disclosure contemplates that the seal member 86 may be a member or an assembly. The seal member 86 is described herein such that a description thereof is not repeated.

In this exemplary embodiment, the jacket locking assembly 660 includes a clasp assembly provided to clasp the jacket lid 640 to the jacket body 620. The clasp assembly may include one or more first members 662 that releasably engages one or more second members 664. In one exemplary embodiment, the clasp assembly may be a snap-fit connection. Non-limiting examples of a snap-fit connections include cantilever snap-fit and torsion snap-fit connections. In the embodiment shown, the snap-fit connection is a cantilever snap-fit connection, where the one or more first members 662 are cantilever arms or beams extending from an edge of the jacket lid 640 or an edge of the jacket body 620, and the one or more second members 664 are shelfs or catches extending from or in the jacket body 22. For ease of description, the one or more first members 662 may also be referred to herein as the “beams” in the plural and the “beam” in the singular. Further, the one or more second members 664 may also be referred to herein as the “catches” in the plural or the “catch” in the singular. The beams 662 can be integral with or monolithically formed into the jacket lid 640 or the jacket body 620. In another embodiment, the beams 662 can be secured to the jacket lid 640 or the jacket body 620 by, for example, welds, adhesives or other fasteners. The one or more catches 664 can be integral with or monolithically formed into the jacket body 620 or the jacket lid 640. In another embodiment, the one or more catches 664 can be secured to the jacket body 620 or the jacket lid 640 by, for example, welds, adhesives or other fasteners. Preferably, the one or more beams 662 extend from the edge 640a of the jacket lid 640, as shown in FIG. 50, allowing a user to exert a force, such as a pressing force, on the jacket lid 640 in the direction of the one or more catches 664. When each beam 662 contacts a corresponding catch 664, seen in FIGS. 48 and 49, further force on the jacket lid 640 causes the beam 662 to flex, shown in phantom in FIG. 49, so that the hook 666 of the beam 662 passes into or onto the catch 664, as shown in FIGS. 48 and 49. When the hook 666 passes the catch 664, the beam 662 snaps back to its original steady state, as shown in solid lines in FIG. 49, so that the hook 666 engages the catch 664 to hold the jacket lid 640 in the closed position. When moving the jacket lid 640 to the open position, the user first disengages the hook 666 of the beam 662 from the catch 664 by applying a force on the hook 666 in order to release the hook 666 from the catch 664. The jacket lid 640 can now be moved to the opened position. It is contemplated that the one or more beams 662 may be located anywhere along the jacket lid 640 and the one or more catch 664 may be located anywhere along the jacket body 620 so long as the one or more beams 662 are aligned with a corresponding one of the one or more catches 664 when the jacket lid 640 is in the closed position.

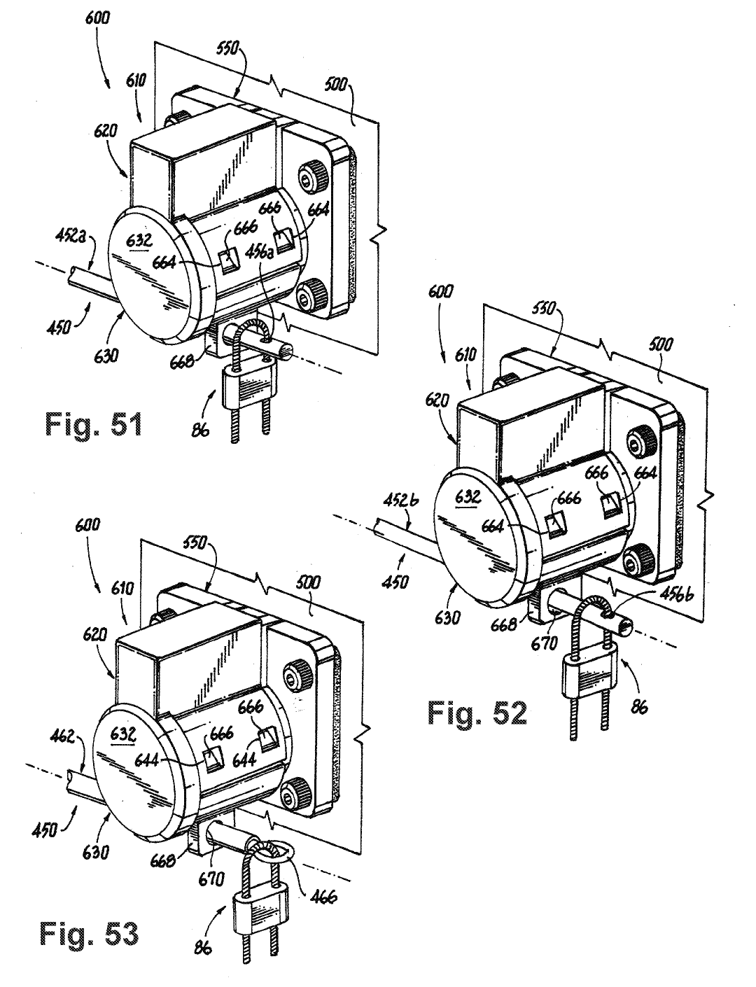

In this exemplary embodiment, the jacket locking assembly 660 may also include a sealing tab 668. The sealing tab 668 includes an aperture 670 extending therethrough that is configured and dimensioned to receive the interlocking member 450. Preferably, the sealing tab 668 is positioned on an exterior or outer wall of the jacket lid 640 so that when the jacket lid 640 is in the closed position, the apertures 670 of each sealing tab 668 of each jacket assembly 600 are aligned to receive the interlocking member 450, as shown in FIGS. 51 and 53. However, as described above, there may be instances where the conventional cover assemblies 550 and thus the jacket assemblies 600 are not precisely aligned on the structure 500, similar to that shown in FIG. 41. In such instances, the interlocking member 450 of FIGS. 48 and 52 may be used to seal the jacket lids 640 to the jacket housings 620 of a plurality of jacket assemblies 600. More specifically, the flexible interlocking member 450 permits a single interlocking member 450 to seal the lids 554 of a plurality of conventional cover assemblies 550. As shown in FIGS. 48 and 51-52, the shafts 452a, 452b or 452c, or the inner rod 460 and outer hollow member 462 shown in FIG. 53, can be passed through the apertures 670 of a plurality of sealing tabs 668 of each jacket assembly 600. Once the shafts 452a, 452b or 452c, or the inner rod 460 and outer hollow member 462 is passed through the apertures 670 of a plurality of sealing tabs 668 of each jacket assembly 600, the seal member 86 can be used to seal the interlocking member 450 to the jacket assemblies 600 so that the single interlocking member 450 seals the plurality of conventional cover assemblies 550, similar to that shown in FIG. 41.

Continuing to refer to FIGS. 48-53, the attachment of a jacket assembly 600 to a conventional cover 550 will be described. As depicted in FIG. 50, the jacket lid 640 of the jacket housing 610 is moved to an open position providing access to the cavity 624, and the jacket body 620 is placed over the conventional cover 550 so that the body 552 of the conventional cover 550 is within the cavity 624 and the cap 630 is positioned on the lid 554 of the conventional cover 550, similar to that shown in FIG. 25. With the jacket body 620 on or over the body 552 of the conventional cover 550, the jacket lid 640 of the jacket housing 610 is moved to the closed position, seen in FIGS. 48 and 51-53, so that the jacket housing 610 surrounds at least a portion of the body 552 and lid 554 of the conventional cover 550. The distal end of the interlocking member 450 is then passed through the apertures 670 of each sealing tab 668 of each of the plurality of the jacket assemblies 600 until the distal end of the interlocking member 450 extend from the last apertures 670 of the last jacket assembly 600. One end of the shackle 92 of the seal member 86 is then passed through the aperture 456a, 456b, or the eyelets 456c or 466 of the interlocking member 450 and through or at least partially into the locking body 94 so that the end of the shackle 92 is locked in the locking body 94. In this configuration, the jacket lid 640 is sealed to the jacket body 620 of each jacket housing 610 to discourage and possibly prevent unauthorized access to the electrical device 400 covered by the conventional covers 550. To break the seal, the shackle 92 would have to be cut. However, as described above, in some embodiments, the locking body 94 of the seal member 86 may have locking mechanism with a key or combination that can be used to unlock the locking mechanism so the shackle 92 can be removed from the locking body 94 to break the seal.

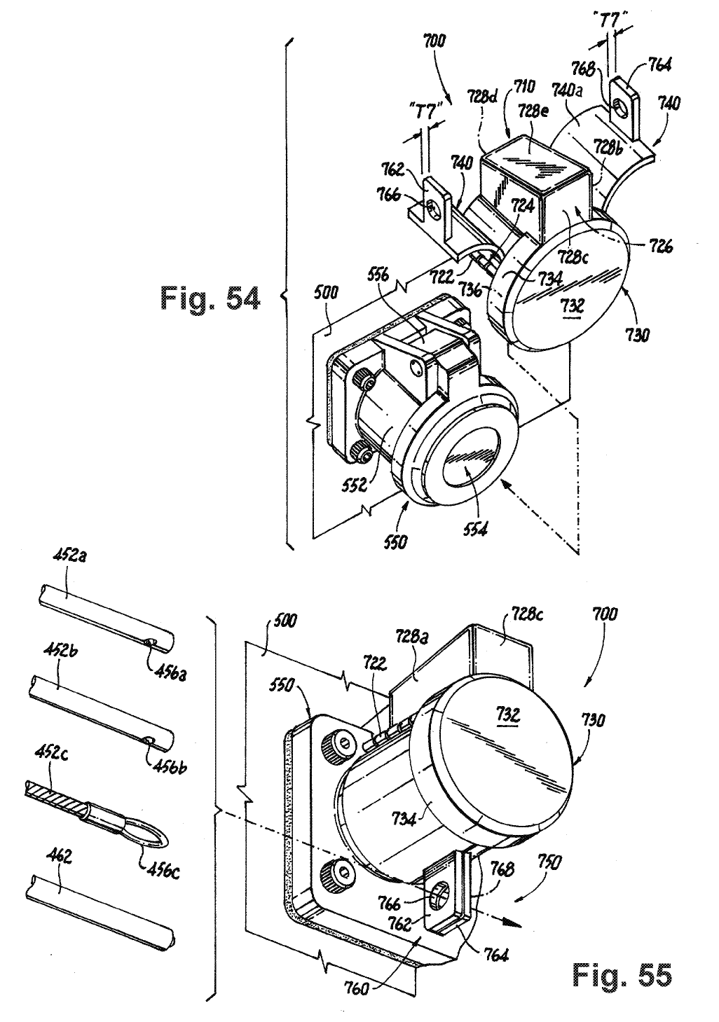

Turning now to FIGS. 54 and 55, another exemplary embodiment of a jacket assembly is shown. In this exemplary embodiment, the jacket assembly 700 is configured to at least partially surround conventional cover assemblies 550 that cover at least the contact portion 402 of the electrical devices 400, seen in FIG. 1, and to couple with such conventional cover assemblies 550 in order to discourage and possibly prevent unauthorized access to the one or more electrical devices 400 covered by the conventional cover assemblies 550. The jacket assemblies 700 described herein may be made of materials that are sufficiently rigid to cover the conventional cover assemblies 550 or portions of the conventional cover assemblies 550 and to discourage and possibly prevent unauthorized access to the one or more electrical devices 400 covered by conventional cover assemblies 550. The jacket assemblies 700 described herein may also be made from materials that may further protect the conventional cover assemblies 550 or portions of the conventional cover assemblies housed within the jacket assemblies 700 from environmental conditions, such as snow, rain, cold and heat. Preferably, the jacket assemblies 700 according to the present disclosure may be made of plastic materials or other non-conductive materials. Non-limiting examples of such plastic materials include thermoplastic materials or combinations of thermoplastic materials. Non-limiting examples of thermoplastic materials include Polycarbonate, Polybutylene Terephthalate (PBT) and Nylon. However, one skilled in the art would understand and appreciate that the jacket assemblies 700 described herein can be made in other ways and from alternative materials without deviating from the scope contemplated by the present disclosure.

The jacket assemblies 700 include a jacket housing 710 and a jacket seal system 750. Each jacket housing 710 is configured and dimensioned to fit onto and at least partially surround the body 552 and lid 554 of a conventional cover assembly 550. In the embodiment shown, the jacket housing 710 includes a jacket body 720 and a plurality of jacket lids 740. The jacket body 720 includes an arcuate shaped structure, and each of the plurality of jacket lids 740 are at least partially arcuate shaped structures. The jacket lids 740 are movably secured to the jacket body 720 by, for example, hinges 722 so that the jacket lids 740 can move between a closed position, seen in FIG. 55, and an open position, seen in FIG. 54. In the closed position, the free ends of the jacket lids 740 can be sealed to the jacket body 720, and in the open position the jacket body 720 can be positioned or inserted onto the conventional cover assembly 550, as shown in FIG. 54. Further, when the jacket lids 640 are in the closed position, the jacket body 720 and the jacket lids 740 form a cavity 724 configured to receive the body 552 of the conventional cover assembly 550, as shown in FIG. 54. The jacket housing 710 may also include a hinge receiving cavity 726, seen in phantom in FIG. 54, formed by one or more walls 728. The hinge receiving cavity 726 is similar to the hinge receiving cavity 178 described herein and shown in FIG. 25. The walls 728 include side walls 728a and 728b, end walls 728c and 728d, and top wall 728e. Preferably, the walls 728 are integrally or monolithically formed into the jacket body 720 so that the hinge receiving cavity 726 is in communication with the cavity 724 formed when the jacket lid 740 is sealed to the jacket body 720. The hinge receiving cavity 726 is configured and dimensioned to receive a hinge 556 connecting the lid 554 to the body 552 of a conventional cover assembly 550. The jacket housing 710 may also include a cap 730 configured and dimensioned to fit over the lid 554 of the conventional cover assembly 550. The cap 730 includes an exterior face 732 and an outer wall 734 extending from the face 732 and defining a cavity 736 to receive the lid 554 of the conventional cover assembly 550, as shown in FIG. 55.

Continuing to refer to FIG. 55, the jacket seal system 750 of the jacket assembly 700 is configured to discourage and possibly prevent the lid 554 of conventional cover assemblies 550 from being moved to the open position, and thus discourage and possibly prevent unauthorized access to the electrical device 400 or the contact portion 402 of the electrical device 400 within the conventional cover assembly 550. Further, the jacket seal system 750 may also provide evidence of tampering. In the embodiment shown in FIGS. 54 and 55, the jacket seal system 750 includes a plurality of jacket locking assemblies 760, an interlocking member or assembly 450 and a seal member or assembly 86. The plurality of jacket locking assemblies 760, interlocking member 450 and seal member 86 are configured and dimensioned to discourage and possibly prevent the lids 554 of a plurality of conventional cover assemblies 550 from being moved to the open position and thus discourage and possibly prevent unauthorized access to the electrical devices or the portion of the electrical devices within the plurality of conventional cover assemblies. For ease of description, the interlocking member or assembly 450 may also be referred to herein as the interlocking member 450 so that the present disclosure contemplates that the interlocking member 450 may be a member or an assembly. The interlocking member 450 is described herein such that a description thereof is not repeated. In addition, the seal member or assembly 86 may also be referred to herein as the seal member 86 so that the present disclosure contemplates that the seal member 86 may be a member or an assembly. The seal member 86 is described herein such that a description thereof is not repeated.

Each jacket locking assembly 760 includes a first sealing tab 762 and a second sealing tab 764. In the embodiment shown, the first sealing tab 762 is a solid member with a rectangular or square shaped cross-section that extends from an outer wall 740a of a first jacket lid 740 and includes an aperture 766 therethrough. The first sealing tab 762 may be integral with or monolithically formed into the outer wall 740a of the first jacket lid 740, or the first sealing tab 762 may be secured to the outer wall 740a with for example welded joints or adhesives. Preferably, the first sealing tab 762 has a predefined thickness “T7” that is sufficient to withstand accidental contact without breaking. The second sealing tab 764 is a solid member with a rectangular or square shaped cross-section that extends from the outer wall 740a of a second jacket lid 740 and includes an aperture 768 therethrough. The second sealing tab 764 may be integral with or monolithically formed into the outer wall 740a of the second jacket lid 740, or the first sealing tab 764 may be secured to the outer wall 740a with for example welded joints or adhesives. Preferably, the second sealing tab 764 has the predefined thickness “T7” that is sufficient to withstand accidental contact without breaking. The apertures 766 and 768 are configured and dimensioned to receive the interlocking member 450, e.g., the shafts 452a, 452b or 452c, or the inner rod 460 and outer hollow member 462 shown in FIGS. 32-36, so that a single interlocking member 450 can seal the jacket lids 740 to the jacket bodies 720 of a plurality of jacket assemblies 700, and thus seal the lids 554 of a plurality of conventional cover assemblies 550 in the closed position.

The first sealing tab 762 is positioned on the outer wall of the first jacket lid 740 and the second sealing tab 764 is positioned on the outer wall of the second jacket lid 740 so that when the jacket lids 740 are in the closed position, the apertures 766 and 768 are in alignment with each other so that at least a portion of the interlocking member 450 can pass through the apertures 766 and 768 when sealing the jacket lids 740 to the jacket bodies 720. The seal member 86 is provided to seal the interlocking member 450 to the jacket lids 740 of the jacket housing 710 to discourage and possibly prevent unauthorized access to the electrical device covered by conventional cover assembly 550. As described herein, the seal member 86 can be used to seal the interlocking member 450 to the jacket assemblies 700 and may include a shackle 92 that can be locked in an irreversible locking body 94 as described herein. The shackle 92 can be passed through the apertures 456a and 456b or the eyelets 456c and 466 at the distal end of the interlocking member 450 and is locked to the irreversible locking body 94 to seal each jacket lids 740 of each of the plurality of jacket assemblies 700 in the closed position. In some embodiments, the locking body 94 of the seal member 86 may have locking mechanism with a key or combination that can be used to unlock the locking mechanism so the shackle 92 can be removed from the locking body 94 to break the seal.

While illustrative embodiments of the present disclosure have been described and illustrated above, it should be understood that these are exemplary of the disclosure and are not to be considered as limiting. Additions, deletions, substitutions, and other modifications can be made without departing from the spirit or scope of the present disclosure. Accordingly, the present disclosure is not to be considered as limited by the foregoing description.

What is claimed is:

1. A cover assembly for covering at least a portion of an electrical device mounted to a structure, the cover assembly comprising:
a housing having a mounting flange, a body extending from the mounting flange and an opening through the mounting flange, the opening being configured to receive at least a portion of the electrical device;
a lid connected to the body and movable relative to the body between a closed position blocking the opening and an open position permitting access to the opening; and
a cover seal system operatively coupled to the housing and the lid and configured to assist in preventing the lid from being moved to the open position limiting access to the at least a portion of the electrical device.

2. The cover assembly according to claim 1, wherein the cover seal system comprises:
a cover seal assembly including a first sealing tab and a second sealing tab, the first sealing tab extends from the body and includes a first aperture therethrough, the second sealing tab extends from the lid and includes a second aperture therethrough, wherein the first aperture is configured to align with the second aperture when the lid is in the closed position; and
a seal member configured to at least partially pass through the first aperture and the second aperture, such that when the lid is in the closed position at least a portion of the seal member can be passed through the first and second apertures.

3. The cover assembly according to claim 2, wherein at least a portion of the seal member is a shackle passing through the first aperture and the second aperture, and wherein the seal member includes a locking body and the shackle is irreversibly or reversibly secured to the locking body.

4. The cover assembly according to claim 3, wherein the shackle comprises a flexible cable or a rigid bar.

5. A cover system for covering a plurality of electrical devices mounted to a structure, the cover system comprising:
a plurality of cover assemblies, each of the plurality of cover assemblies includes:
a housing having a mounting flange, a body extending from the mounting flange and an opening through the mounting flange, the opening being configured to receive at least a portion of one of the plurality of electrical devices;
a lid connected to the body and movable relative to the body between a closed position blocking the opening and an open position permitting access to the opening; and
a cover seal system operatively coupled to the housing and the lid, and configured to assist in preventing the lid from being moved to the open position limiting access to at least a portion of the one of the plurality of electrical devices; and
an interlocking member operatively coupled to each of cover seal system to facilitate the sealing each lid to each housing in the closed position.

6. The cover system according to claim 5, wherein the interlocking member comprises an elongated shaft having an aperture at a distal end.

7. The cover system according to claim 5, wherein the interlocking member comprises an elongated shaft having an eyelet at a distal end.

8. The cover system according to claim 5, wherein the interlocking member comprises an outer hollow member and an inner rod within the outer hollow member, the inner rod being movable within the outer hollow member between a loaded position and a deployed position.

9. The cover system according to claim 8, wherein the inner rod has an eyelet at a distal end, and wherein when the inner rod is in the loaded position the eyelet is within the outer hollow member and when the inner rod is in the deployed position the eyelet extends from a distal end of the outer hollow member.

10. The cover system according to claim 5, wherein each cover seal system comprises:
a cover seal assembly including a first sealing tab and a second sealing tab, the first sealing tab extends from the body and includes a first aperture therethrough, the second sealing tab extends from the lid and includes a second aperture therethrough, wherein the first aperture is configured to align with the second aperture when the lid is in the closed position, wherein the interlocking member passes through each first aperture and each second aperture; and
a seal member configured to be at least partially coupled to the interlocking member to prevent the interlocking member from being removed from each first aperture and each second aperture.

11. The cover system according to claim 10, wherein the seal member comprises a shackle configured to pass through the interlocking member and locking body, and wherein the shackle is irreversibly or reversibly secured to the locking body.

12. The cover system according to claim 9, wherein the shackle comprises a flexible cable or a rigid bar.

13. A cover system for covering a plurality of electrical devices mounted to a structure, the cover system comprising:
a plurality of cover assemblies, each of the plurality of cover assemblies includes:
a housing having a mounting flange, a body extending from the mounting flange and an opening through the mounting flange, the opening being configured to receive at least a portion of one of the plurality of electrical devices;
a lid connected to the body and movable relative to the body between a closed position blocking the opening and an open position permitting access to the opening; and
a cover seal assembly including a first sealing tab and a second sealing tab, the first sealing tab extends from the body and includes a first aperture therethrough, the second sealing tab extends from the lid and includes a second aperture therethrough, wherein the first aperture is configured to align with the second aperture when the lid is in the closed position; and
an interlocking member configured to be passed through each first aperture and each second aperture of each cover seal assembly and to facilitate sealing each lid in the closed position; and
a seal member configured to be at least partially coupled to the interlocking member to prevent the interlocking member from being removed from each first aperture and each second aperture.

14. The cover system according to claim 13, wherein the interlocking member comprises an elongated shaft having an aperture at a distal end.

15. The cover system according to claim 13, wherein the interlocking member comprises an elongated shaft having an eyelet at a distal end.

16. The cover system according to claim 13, wherein the seal member comprises a shackle passing through the first aperture and the second aperture, and wherein the seal member includes a locking body and the shackle is irreversibly or reversibly secured to the locking body.

17. The cover system according to claim 16, wherein the shackle comprises a flexible cable or a rigid bar.

18. The cover system according to claim 13, wherein the interlocking member comprises an elongated shaft having an aperture at a distal end.

19. The cover system according to claim 13, wherein the interlocking member comprises an elongated shaft having an eyelet at a distal end.

20. The cover system according to claim 13, wherein the interlocking member comprises an outer hollow member and an inner rod within the outer hollow member, the inner rod being movable within the outer hollow member between a loaded position and a deployed position.
